(19) United States
(12) Patent Application Publication
(10) Pub. No.: US 2024/0222436 A1
(43) Pub. Date: Jul. 4, 2024

(54) SEMICONDUCTOR MODULE

(71) Applicant: FUJI ELECTRIC CO., LTD., Kanagawa (JP)

(72) Inventor: Takashi TSUJI, Matsumoto-city (JP)

(21) Appl. No.: 18/489,028

(22) Filed: Oct. 18, 2023

(30) Foreign Application Priority Data
Dec. 28, 2022 (JP) 2022-211748
Mar. 27, 2023 (JP) 2023-050018

(51) Int. Cl. H01L 29/16; H01L 27/06; H01L 27/092; H01L 29/10; H01L 29/417; H01L 29/872

(52) U.S. Cl. CPC H01L 29/1608; H01L 27/0629; H01L 27/0921; H01L 29/1095; H01L 29/41766; H01L 29/8725

(57) ABSTRACT

Provided is a semiconductor module including a plurality of SiC chips electrically connected in parallel and each having a MOSFET and a parasitic transistor formed therein, and a control unit which controls switching of the MOSFET in each of the SiC chips, and for all of the plurality of SiC chips, at least in a state where the parasitic transistor is turned on, the control unit controls, to 0.9 μs or less, a turn-off time of the MOSFET corresponding.

The contents of the following patent application(s) are incorporated herein by reference:
NO. 2022-211748 filed in JP on Dec. 28, 2022
NO. 2023-050018 filed in JP on Mar. 27, 2023

### BACKGROUND

### 1. Technical Field

The present invention relates to a semiconductor module.

### 2. Related Art

It is known that in a semiconductor device such as a SiC MOSFET, avalanche breakdown occurs in an unclamped inductive switching (UIS) test or the like (for example, see Non-Patent Document 1).
Non-Patent Document 1: A. Konstantinov, F. Allerstam, H. Pham, G. Park, K. S. Park, D. Waible, and T. Neyer, “Critical temperature and failure mechanism of SiC Schottky rectifiers in Unclamped Inductive Switching (UIS)”, Proceedings of the 2020 32nd International Symposium on Power Semiconductor Devices and ICs (ISPSD), 2020, pp. 158-161

### BRIEF DESCRIPTION OF THE DRAWINGS

FIG. 1 is a diagram for explaining a configuration of a semiconductor module 100 according to one embodiment of the present invention.

FIG. 2 is a diagram for explaining each switching unit 20.

FIG. 3 is a diagram illustrating an example of a cross section of a SiC chip 22.

FIG. 4 is a cross-sectional view illustrating an example of a SiC chip 122 according to a reference example.

FIG. 5 is a diagram illustrating an example of a measurement circuit 200 which measures characteristics of a device under test (DUT).

FIG. 6 is a diagram illustrating an example of waveforms of a drain voltage and a drain current in a UIS test.

FIG. 7 is a diagram illustrating a measurement result of an avalanche allowable current density J_{AV} when a load inductance L is changed in the UIS test.

FIG. 8 is a diagram illustrating a measurement result of an avalanche holding energy E_{AV} when the load inductance L is changed in the UIS test.

FIG. 9 is a diagram illustrating a measured waveform in the UIS test when a supply voltage Vcc applied to the DUT is 300 V.

FIG. 10 is a diagram illustrating a measured waveform in the UIS test when the supply voltage Vcc applied to the DUT is 1150 V.

FIG. 11 is a diagram illustrating a change in avalanche capability when an avalanche breakdown period t_{AV} is changed.

FIG. 12 is a diagram illustrating another example of the measurement circuit 200.

FIG. 13 illustrates a drain voltage and a drain current at a SiC chip 22-1 and a SiC chip 22-2.

FIG. 14A is a table illustrating whether a parasitic transistor of the SiC chip 22 has operated when a local region is present.

FIG. 14B is a diagram illustrating another example of a cross section of the SiC chip 22.

FIG. 14C is a diagram illustrating another example of the cross section of the SiC chip 22.

FIG. 14D is a diagram illustrating another example of the cross section of the SiC chip 22.

FIG. 14E is a diagram illustrating another example of the cross section of the SiC chip 22.

FIG. 14F is a diagram illustrating an example of a YZ cross section passing through a d-d line in FIGS. 14D and 14E.

FIG. 14G is a diagram illustrating another example of the YZ cross section passing through the d-d line.

FIG. 14H is a diagram illustrating another example of the cross section of the SiC chip 22.

FIG. 15 is a diagram for checking that there is no device damage before device failure.

FIG. 16 illustrates the load inductance dependency of the avalanche allowable current density J_{AV} at an ambient temperature of 25° C.

FIG. 17 illustrates the load inductance dependency of the avalanche holding energy E_{AV} at an ambient temperature of 25° C.

FIG. 18 is a diagram illustrating a relationship between E_{AV} and a square root t_{AV}^{1/2} of avalanche duration in a SiC trench diode.

FIG. 19 is a graph in which actual measured waveforms of a UIS test at the time of failure and at the last before the failure in a SiC trench MOSFET and the diode in each region of Low-L to High-L are superimposed.

FIG. 20 is a diagram illustrating the actual measured waveforms of the UIS test.

FIG. 21 is a diagram plotting the temperature dependency of the breakdown voltage of the SiC trench MOSFET.

FIG. 22A is a diagram illustrating trajectories of an estimated lattice temperature and J_{DS} at the last before the failure and at the time of failure in the UIS test.

FIG. 22B is a diagram illustrating trajectories of an estimated lattice temperature and J_{DS} at the last before the failure and at the time of failure in the UIS test.

FIG. 22C is a diagram illustrating trajectories of an estimated lattice temperature and J_{DS} at the last before the failure and at the time of failure in the UIS test.

FIG. 23 is a schematic view of a secondary electron microscope image of the source Al metal surface of the SiC trench MOSFET in which avalanche breakdown occurs at 175° C. and 1 mH.

FIG. 24 is a diagram illustrating a device structure of the SiC trench MOSFET.

FIG. 25 is a diagram illustrating a device structure of the SiC trench diode.

FIG. 26 is a diagram illustrating simulation waveforms of the SiC trench MOSFET and the SiC trench diode at load inductances of 1 μH (Low-L), 10 μH (Medium-L), and 5 mH (High-L).

FIG. 27A is a schematic view illustrating an electron current density distribution in a device cross section.

FIG. 27B illustrates times 1, 2, 3, and 4.

FIG. 28 is a diagram illustrating temporal changes of an electron current density Jₑ, a lattice temperature, and a potential V_{A} at the load inductance of 1 μH (Low-L).

FIG. 29 is a diagram illustrating temporal changes of the electron current density Jₑ, the lattice temperature, and the potential V_{A} at the load inductance of 10 μH (Medium-L).

FIG. 30 is a diagram illustrating temporal changes of the electron current density Jₑ, the lattice temperature, and the potential V_{A} at the load inductance of 5 μH (High-L).

FIG. 31 is a diagram in which the avalanche capability is evaluated by setting a gate V_{GS} of the DUT to −10 V or −20 V.

FIG. 32 is a diagram in which the avalanche capability is evaluated by setting the gate V_{GS} of the DUT to −10 V or −20 V.

FIG. 33A is a diagram in which verification of a MOS channel current is performed in device simulation.

FIG. 33B is a diagram in which the verification of the MOS channel current is performed in the device simulation.

FIG. 34 is a diagram illustrating total current density distributions at V_{GS}=0 V and −10 V in an upper line C1 of FIG. 33.

FIG. 35 is a diagram illustrating a current density distribution under the same V_{GS} condition in a lower line C2 of FIG. 33.

FIG. 36 is a diagram illustrating a hole mobility and temperature characteristics when an acceptor concentration of a base region is changed in the device simulation.

FIG. 37 is a diagram illustrating a hole concentration and the temperature characteristics when the acceptor concentration of the base region is changed in the device simulation.

FIG. 38 is a diagram illustrating a resistance value and the temperature characteristics of the base region when the acceptor concentration of the base region is changed in the device simulation.

### DESCRIPTION OF EXEMPLARY EMBODIMENTS

Hereinafter, the present invention will be described through embodiments of the present invention, but the following embodiments do not limit the present invention according to claims. In addition, not all of the combinations of features described in the embodiments are essential to the solving means of the invention.

Unless otherwise stated, an SI unit system is used as a unit system in the present specification. Although a unit of length may be expressed using cm, it may be converted to meters (m) before calculations. In the present specification, a case where a term such as “same” or “equal” is mentioned may include a case having an error due to a variation in manufacturing or the like. This error is within a range of 10% or less, for example. In the present specification, references to directions such as “perpendicular,” “parallel,” or “along” may be used even when there is an error caused due to a variation in a fabrication step or the like. This error is within a range of 5 degrees or less, for example.

In the present specification, a conductivity type of a doping region where doping has been carried out with an impurity is described as a P type or an N type. The N type is an example of a first conductivity type, and the P type is an example of a second conductivity type. In the present specification, doping means introducing the donor or the acceptor into the semiconductor substrate and turning it into a semiconductor showing the conductivity type of the N type, or a semiconductor showing the conductivity type of the P type. In the present specification, reference to a P+ type or an N+ type means that a doping concentration is high in comparison with the P type or the N type, and reference to a P− type or an N-type means that a doping concentration is low in comparison with the P type or the N type.

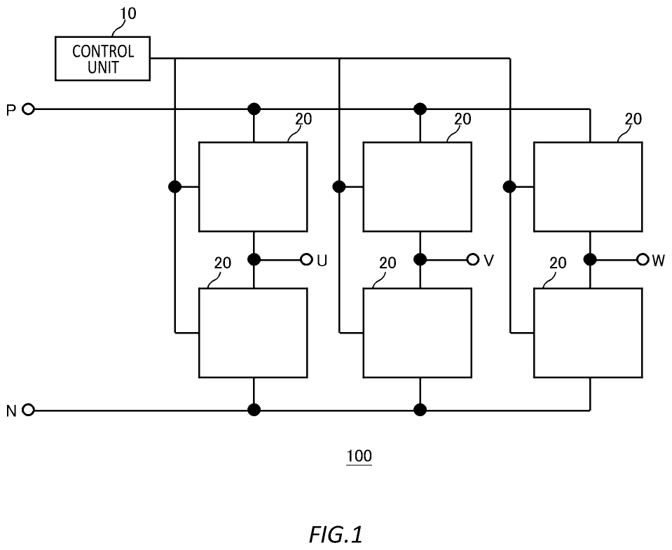

FIG. 1 is a diagram for explaining a configuration of a semiconductor module 100 according to one embodiment of the present invention. The semiconductor module 100 includes a housing formed of a dielectric material such as resin, and an electric circuit accommodated inside the housing. In FIG. 1, at least a part of the electric circuit is shown, and the housing is omitted.

The semiconductor module 100 includes a plurality of switching units 20 and a control unit 10 that controls the switching units 20. The switching unit 20 includes a MOSFET. The control unit 10 outputs a gate signal to be applied to the gate terminal of the MOSFET.

The electric circuit of the semiconductor module 100 illustrated in FIG. 1 is a three-phase inverter, but the electric circuit is not limited thereto. The semiconductor module 100 in the example of FIG. 1 has a P terminal, an N terminal, a U terminal, a V terminal, and a W terminal. A predetermined supply voltage is applied to the P terminal and the N terminal. The semiconductor module 100 of this example includes two switching units 20 for each of the U phase, the V phase, and the W phase. When each of the switching units 20 performs a switching operation, a U signal, a V signal, and a W signal having different phases are output from the U terminal, the V terminal, and the W terminal.

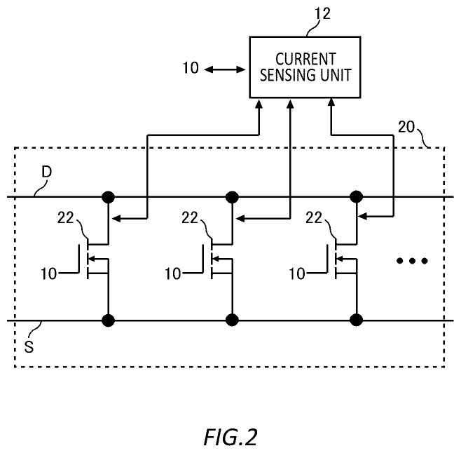

FIG. 2 is a diagram for explaining each switching unit 20. The switching unit 20 includes a plurality of SiC chips 22 electrically connected to each other in parallel. As will be described later, a MOSFET and a parasitic transistor are formed in each SiC chip 22. In the example of FIG. 2, a plurality of MOSFETs (SiC chips 22) is connected to each other in parallel between a drain line D and a source line S. Each SiC chip 22 may be provided with a freewheeling diode connected in antiparallel with the MOSFET. In FIG. 2, the freewheeling diode is omitted.

The control unit 10 controls switching of the MOSFET in each of the plurality of SiC chips 22. In the example of FIG. 2, the same gate signal is input from the control unit 10 to the gate terminals of the plurality of SiC chips 22 included in one switching unit 20. Each of the drain line D and the source line S is connected to one of the terminals illustrated in FIG. 1.

In the SiC chip 22, it is relatively difficult to increase a chip size, and it is difficult to cause a large drain current to flow. The plurality of SiC chips 22 is provided in parallel, so that the drain current of one switching unit 20 can be increased. However, when the plurality of SiC chips 22 is provided in parallel, if the turn-off timing of a specific SiC chip 22 is delayed due to a variation in gate threshold voltage or the like, current concentrates on the SiC chip 22. Therefore, in the configuration in which the plurality of SiC chips 22 is provided in parallel, it is preferable to increase the avalanche capability of each SiC chip 22.

The semiconductor module 100 may further include a current sensing unit 12. The current sensing unit 12 senses the current (for example, a drain current) flowing through at least one SiC chip 22 of the plurality of SiC chips 22. The current sensing unit 12 may sense the current flowing through all of the SiC chips 22 for each SiC chip 22.

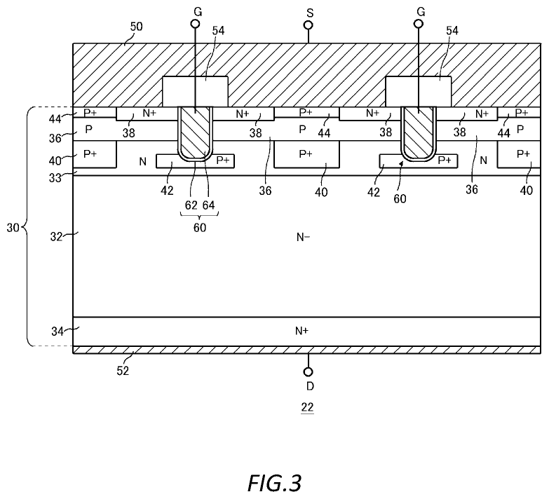

FIG. 3 is a diagram illustrating an example of a cross section of the SiC chip 22. The SiC chip 22 of this example includes a semiconductor substrate 30, a source electrode 50, a drain electrode 52, and an interlayer dielectric film 54. The source electrode 50 and the drain electrode 52 are formed of a conductive material in which various types of metal such as aluminum are stacked. The source electrode 50 is provided on the upper surface of the semiconductor substrate 30, and the drain electrode 52 is provided on the lower surface of the semiconductor substrate 30.

The semiconductor substrate 30 is formed of silicon carbide (SIC). The semiconductor substrate 30 may be a substrate obtained by cutting a wafer from a SiC ingot and singulating the wafer, and may further include a portion formed by epitaxial growth or the like on the substrate.

A source region 38 of the N+ type, a contact region 44 of the P+ type, a gate trench portion 60, a base region 36 of the P type, a drift region 32 of the N− type, and a drain region 34 of the N+ type are provided inside the semiconductor substrate 30 of this example. The semiconductor substrate 30 may be further provided with a region 33 of the N type, a region 40 of the P+ type, and a lower end region 42 of the P+ type.

The gate trench portion 60 has a groove portion provided from the upper surface to the inside of the semiconductor substrate 30. The inner wall of the groove portion is covered with a gate dielectric film 62 such as an oxide film. The groove portion is provided with a gate electrode 64 formed of a conductive material such as polysilicon. The gate electrode 64 and the semiconductor substrate 30 are insulated by the gate dielectric film 62. In addition, the gate electrode 64 and the source electrode 50 are insulated from each other by the interlayer dielectric film 54. The interlayer dielectric film 54 is, for example, a dielectric film such as BPSG.

The source region 38 is exposed on the upper surface of the semiconductor substrate 30 and connected to the source electrode 50. The source region 38 is in contact with the gate dielectric film 62 of the sidewall of the gate trench portion 60. The contact region 44 is exposed on the upper surface of the semiconductor substrate 30 and connected to the source electrode 50. The contact region 44 may be disposed apart from the gate trench portion 60.

The base region 36 is disposed below the source region 38 so as to be in contact with the gate dielectric film 62 of the sidewall of the gate trench portion 60. When a predetermined ON voltage is applied to the gate electrode 64, a channel of electrons is formed at the surface layer of the base region 36 in contact with the gate trench portion 60.

The drift region 32 is provided below the base region 36. When a channel is formed in the base region 36, the source region 38 and the drift region 32 are electrically connected, and a drain current flows. The region 33 of the N type having a doping concentration higher than that of the drift region 32 may be provided between the base region 36 and the drift region 32. The drift region 32 may be provided instead of the region 33. In addition, the region 40 of the P+ type may be provided between the base region 36 and the drift region 32 below the contact region 44. In addition, the lower end region 42 of the P+ type may be provided so as to cover the lower end of the gate trench portion 60. By providing the lower end region 42, it is possible to relax electric field strength on the lower end of the gate trench portion 60.

The drain region 34 is disposed between the drift region 32 and the lower surface of the semiconductor substrate 30. The drain region 34 is exposed on the lower surface of the semiconductor substrate 30 and connected to the drain electrode 52.

The SiC chip 22 has a MOSFET and a parasitic transistor. For example, a region including the gate trench portion 60, the source region 38, the base region 36, the drift region 32, and the drain region 34 operates as a MOSFET. For example, the source region 38, the base region 36, and the N region 33 operate as a parasitic transistor (in this example, a bipolar junction transistor (BJT)). In the present specification, the parasitic transistor of the SiC chip 22 may be referred to as the BJT.

When the parasitic transistor becomes the on state, an electron current flows through the parasitic transistor. The electrons having reached the drift region 32 drift due to a high electric field in the drift region 32, and electron-hole pairs are generated by collision ionization. As a result, a hole current flows through the base region 36, a potential barrier of a pn junction between the base region 36 and the source region 38 becomes small, and an electron current further flows through the parasitic transistor. Such positive feedback may cause the avalanche capability of the SiC chip 22 to decrease.

For all of the SiC chips 22 included in the semiconductor module 100, at least in a state where the parasitic transistors are turned on, the control unit 10 of this example controls the turn-off time of the corresponding MOSFETs to 0.9 μs or less. The turn-off time is time required to cause the MOSFET to transition from the on state to the off state. The drain current immediately before the gate voltage of the MOSFET is caused to transition to the off-voltage is denoted by I_{DS_ON}. In the present specification, the turn-off time is time from a time point at which a drain current I_{DS} becomes 0.9×I_{DS_ON} for the first time to a time point at which the drain current I_{DS} becomes 0.1×I_{DS_ON} for the first time after the gate voltage of the MOSFET is caused to transition to the off-voltage. That is, the turn-off time is time during which the drain current of the MOSFET decreases from 90% to 10% of the drain current I_{DS_ON} at the time of the on state.

In the present specification, the turn-off time of the MOSFET in the state where the parasitic transistor is turned on may be referred to as a first turn-off time. By shortening the first turn-off time, the MOSFET can be turned off before the electron current of the parasitic transistor excessively increases, and the failure of the SiC chip 22 due to the operation of the parasitic transistor can be suppressed. The control unit 10 may control the first turn-off time to 0.9 μs or less, 0.8 μs or less, or 0.7 μs or less.

The state where the parasitic transistor is turned on refers to a state where a voltage drop ΔV between the base region 36 and the source electrode 50 is equal to or higher than a built-in potential V_{bi} of the pn junction between the base region 36 and the source region 38. The voltage drop ΔV in the base region 36 is determined by a contact resistance R_{c} between the base region 36 and the source electrode 50 (in this example, a contact resistance between the source electrode 50 and the contact region 44), a resistance Rₛ of the base region 36, and a hole current Iₕ flowing from the source electrode 50 to the base region 36 as in the following expression.

ΔV=(R_{c}+Rₛ)Iₕ

The control unit 10 may control the turn-off time of the MOSFET to the first turn-off time (for example, 0.9 μs or less) at least in a situation where the voltage drop ΔV is equal to or higher than the built-in potential V_{bi}. The contact resistance R_{c} and the resistance Rₛ of the base region 36 can distinguish whether the parasitic transistor is in an on state or an off state according to the value of the hole current Iₕ.

The control unit 10 may monitor the hole current Iₕ and change the turn-off time of the MOSFET based on a comparison result between the current value and a predetermined reference value. The control unit 10 may compare the drain current detected by the current sensing unit 12 with the predetermined reference value.

The turn-off time of the MOSFET can be adjusted by the absolute value of the off-voltage (negative bias in this example) applied to the gate terminal of the SiC chip 22 when the SiC chip 22 is turned off. For example, when a difference between the off-voltage and the on-voltage when the SiC chip 22 is turned on is increased, the turn-off time is shortened. In a state where the parasitic transistor is turned off, the control unit 10 may set the turn-off time of the MOSFET to a value larger than the first turn-off time (for example, a value larger than 0.9 μs). The value of the off-voltage generated by the control unit 10 in each of the state where the parasitic transistor is turned on and the state where the parasitic transistor is turned off may be set in the control unit 10 in advance. That is, the value of the off-voltage for setting the turn-off time of the MOSFET to the first turn-off time and the value of the off-voltage for setting the first turn-off time to a value larger than the first turn-off time may be set in the control unit 10 in advance. The turn-off time of the MOSFET can also be adjusted by the resistance value of the gate resistor connected to the gate terminal of the MOSFET. For example, when the resistance value of the gate resistor is increased, the turn-off time is also increased, and when the resistance value of the gate resistor is decreased, the turn-off time is also shortened. The turn-off time of the MOSFET may be adjusted by the voltage value of the off-voltage applied to the gate terminal, may be adjusted by the resistance value of the gate resistor, may be adjusted by a combination thereof, or may be adjusted by another method.

The control unit 10 may collectively control the turn-off times of the MOSFETs of all of the SiC chips 22 included in one switching unit 20. For example, when the drain current flowing through any of the SiC chips 22 becomes equal to or larger than the reference value, the control unit 10 may control the turn-off times of all of the SiC chips 22 included in the switching unit 20 to the first turn-off time.

In another example, depending on the state of the parasitic transistor of each of the plurality of SiC chips 22, the control unit 10 may individually control the turn-off time of the corresponding MOSFET. For example, the current sensing unit 12 may sense the drain current flowing through each SiC chip 22, and the control unit 10 may control the turn-off time of the corresponding SiC chip 22 based on each drain current. The control unit 10 may control, to the first turn-off time, the turn-off time of the SiC chip 22 in which the drain current is equal to or larger than the reference value, and control, to a time longer than the first turn-off time, the turn-off time of the SiC chip 22 in which the drain current is less than the reference value.

Even in a state where the parasitic transistor is turned off, the control unit 10 of another example may control the turn-off time of the corresponding MOSFET to a value similar to the first turn-off time (for example, 0.9 μs or less). That is, the control unit 10 may generate a constant off-voltage regardless of the state of the parasitic transistor. In this case, the semiconductor module 100 may not include a current sensor which detects the hole current Iₕ (or the drain current flowing through the SiC chip 22). Before shipment of the semiconductor module 100, the off-voltage may be set in the control unit 10. The off-voltage may be common to all of the switching units 20 or may be different. In addition, the off-voltage may be common to the SiC chips 22 included in one switching unit 20 or may be different.

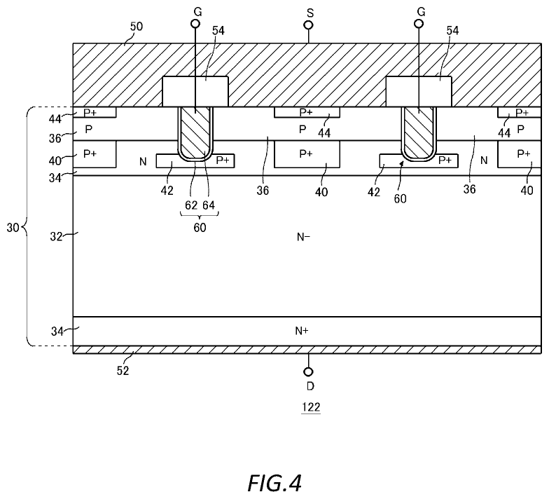

FIG. 4 is a cross-sectional view illustrating an example of a SiC chip 122 according to a reference example. The SiC chip 122 is different from the SiC chip 22 illustrated in FIG. 3 in that the source region 38 is not provided. In the example of FIG. 4, the base region 36 is provided instead of the source region 38. The SiC chip 22 is provided with the MOSFET, and the SiC chip 122 is provided with a diode. In the present specification, an element provided in the SiC chip 22 may be referred to as a SiC trench MOSFET, and an element provided in the SiC chip 122 may be referred to as a SiC trench diode. The SiC chip 122 is not provided with a parasitic transistor. The size and doping concentration of the corresponding elements are the same in the SiC chip 22 and the SiC chip 122.

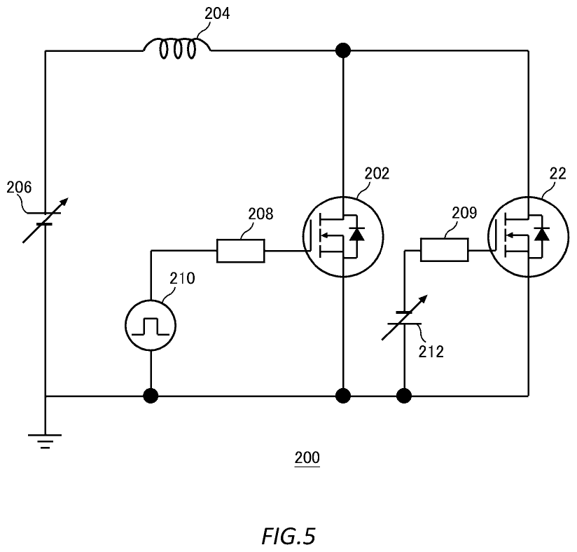

FIG. 5 is a diagram illustrating an example of a measurement circuit 200 which measures characteristics of a device under test (DUT). The measurement circuit 200 performs an unclamped inductive switching test (UIS test) of a device under test. In the example of FIG. 5, the device under test DUT is the SiC chip 22. The measurement circuit 200 includes a drive device 202, a load inductor 204, a power supply 206, a pulse generator 210, a gate resistor 208, a gate resistor 209, and a gate control unit 212. In the present specification, the inductance of the load inductor 204 may be referred to as a load inductance L.

The power supply 206 generates supply power and supplies the supply power to the drive device 202 and the DUT via the load inductor 204. The drive device 202 is connected in parallel with the DUT. The drive device 202 is a MOSFET having a higher breakdown voltage than the SiC chip 22. In addition, in the drive device 202, the area of an active region through which a main current flows is larger than that of the SiC chip 22, and a drain current larger than that of the SiC chip 22 can flow.

The pulse generator 210 applies a gate signal to the drive device 202 via the gate resistor 208 to control switching of the drive device 202. The gate control unit 212 applies a gate voltage to the DUT via the gate resistor 209 to control the DUT to be turned on.

When the drive device 202 is switched to the on state for a predetermined period and then switched to the off state, the current corresponding to the current flowing through the drive device 202 flows through the DUT by the load inductor 204. Such control allows a large current to flow through the DUT. In the UIS test, processing of gradually increasing the supply voltage generated by the power supply 206 and causing the drive device 202 to transition from the on state to the off state at each supply voltage is repeated. Then, the supply voltage in the processing when the DUT fails and the supply voltage in the processing immediately before the failure are detected. In the present specification, the processing (or measurement) when the DUT fails may be referred to as fail, and the processing (or measurement) immediately before the DUT fails may be referred to as last. In the UIS test, the drain current flowing through the DUT in the processing immediately before the DUT fails may be measured. In the present specification, a value obtained by dividing the drain current by the area of the active region of the chip is referred to as a drain current density. The active region is a region, such as a MOSFET or a diode, in which current flows between the upper surface and the lower surface of the semiconductor substrate 30. The region covered with the source electrode 50 may be regarded as the active region. The area of the active region refers to an area when viewed from a direction perpendicular to the upper surface of the semiconductor substrate 30. In the present specification, the peak value of the drain current density in the processing immediately before the DUT fails is referred to as an avalanche allowable current density J_{AV}(A/cm²), and a value obtained by integrating the product of the drain voltage and the drain current at each time during the avalanche breakdown period within the avalanche breakdown period and dividing the result by the area of the active region is referred to as an avalanche holding energy E_{AV}(J/cm²). The avalanche allowable current density J_{AV} and the avalanche holding energy E_{AV} indicate the avalanche capability of the DUT.

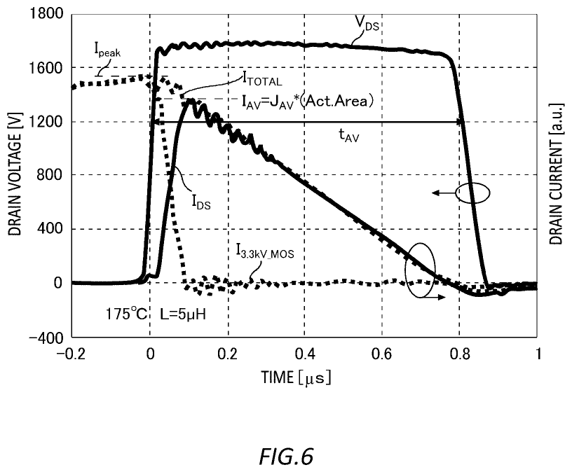

FIG. 6 is a diagram illustrating an example of waveforms of the drain voltage and the drain current in the UIS test. In FIG. 6, I_{DS} is the current flowing through the DUT, I_{3.3kv_MOS} is the current flowing through the drive device 202, and I_{TOTAL} is the sum of the currents flowing through the drive device 202 and the DUT (I_{DS}+ I_{3.3kv_MOS}). In addition, V_{DS} is the drain voltage of the DUT.

In the example of FIG. 6, the drive device 202 is caused to transition from on to off at the timing of time 0. As I_{3.3kv_MOS} decreases, I_{DS} increases, and the drain current I_{DS} corresponding to a peak value Iₚₑₐₖ of I_{3.3kv_MOS} flows through the DUT. The peak value of the drain current I_{DS} is denoted by lav. The peak value I_{AV} of the drain current is a value obtained by multiplying the peak value J_{AV} of the drain current density by an area Act.Area. of the active region.

An avalanche breakdown period of the DUT such as the SiC chip 22 is defined as t_{AV}. The avalanche breakdown period t_{AV} is time from a rising edge to a falling edge of the drain voltage V_{DS}. The avalanche breakdown period t_{AV} increases as the load inductance L increases.

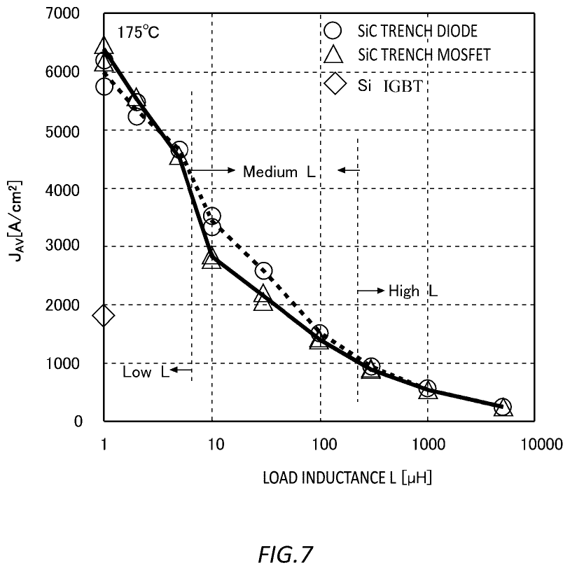

FIG. 7 is a diagram illustrating a measurement result of the avalanche allowable current density J_{AV} when the load inductance L is changed in the UIS test. The UIS test of this example was performed at an ambient temperature of 175° C. In this example, a case where the DUT is the SiC chip 22 (SiC trench MOSFET) is compared with a case where the DUT is the SiC chip 122 (SiC trench diode). In addition, an example in which the DUT is an IGBT of silicon is also illustrated.

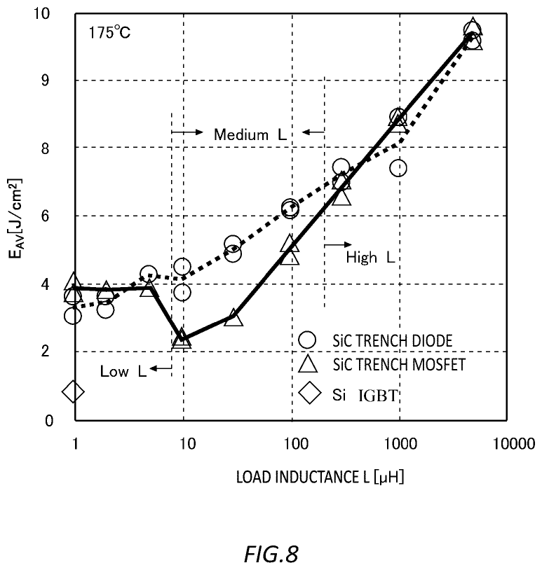

FIG. 8 is a diagram illustrating a measurement result of the avalanche holding energy E_{AV} when the load inductance L is changed in the UIS test. The UIS test of this example was performed at an ambient temperature of 175° C. In this example, a case where the DUT is the SiC chip 22 (SiC trench MOSFET) is compared with a case where the DUT is the SiC chip 122 (SiC trench diode). In addition, an example in which the DUT is an IGBT of silicon is also illustrated.

As illustrated in FIGS. 7 and 8, in a low L region (Low L) in which the load inductance L is relatively low and a high L region (High L) in which the load inductance L is relatively large, the avalanche capability of the SiC trench MOSFET and the avalanche capability of the SiC trench diode are equivalent. On the other hand, in an intermediate L region (Medium L) in which the load inductance L is an intermediate value, the avalanche capability of the SiC trench MOSFET is lower than the avalanche capability of the SiC trench diode. The intermediate L region includes, for example, a region of 10 μl to 100 μH.

In the SiC trench diode, a parasitic transistor is not provided. The avalanche capability of the SiC trench diode is considered to be a withstand capability to thermal failure. The thermal failure occurs when the internal temperature of the semiconductor substrate 30 increases due to Joule heat generated by the flow of the current and exceeds a predetermined thermal failure critical temperature. As illustrated in FIG. 8, in the SiC trench diode, the avalanche holding energy E_{AV} monotonously increases as the load inductance L increases. This is considered that under the assumption that the failure of the DUT occurs at the time of reaching a certain critical temperature, when the load inductance L is small, the avalanche breakdown period is shortened (which leads to an increase in the current value), and the generated heat mostly remains in the drift layer (adiabatic). On the other hand, it is considered that it is because when the load inductance L is increased, the avalanche breakdown period increases, and the heat is diffused to the outside, so that the energy for achieving the critical temperature increases.

The thermal failure described above also occurs in the SiC trench MOSFET. However, in the intermediate L region, it is considered that the parasitic transistor of the SiC trench MOSFET operates, the above-described positive feedback is applied, and the avalanche capability decreases. In order for the parasitic transistor to undergo a positive feedback operation, the internal temperature of the semiconductor substrate 30 needs to be equal to or higher than a predetermined positive feedback critical temperature. In a region where the load inductance L is small, the avalanche breakdown period t_{AV} is short, and thus the diffusion length of heat becomes small. Therefore, the temperature easily increases locally, and reaches the critical temperature with lower energy. In the examples of FIGS. 7 and 8, in the region where the load inductance L is 10 μH or more, the parasitic transistor of the SiC trench MOSFET undergoes the positive feedback operation, and the avalanche capability decreases. On the other hand, when the load inductance L is large, the avalanche breakdown period t_{AV} becomes long, and the diffusion length of heat becomes long. Therefore, larger energy is required to reach the positive feedback critical temperature. Therefore, in the intermediate L region, as the load inductance L increases, the avalanche capability of the SiC trench MOSFET rises.

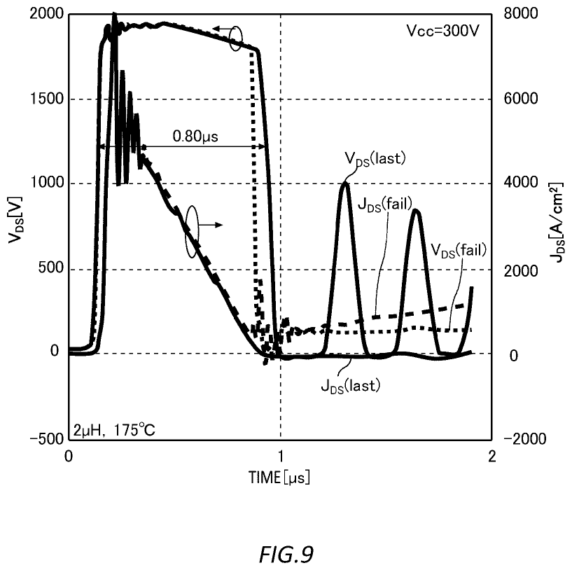

FIG. 9 is a diagram illustrating a measured waveform in the UIS test when a supply voltage Vcc applied to the DUT is 300 V. In the UIS test of this example, the load inductance L is 2 μH, and the ambient temperature is 175° C. The DUT of this example is the SiC chip 22 (SiC trench MOSFET). The breakdown voltage of the SiC chip 22 is 1.2 kV. Unless otherwise described herein, the DUT in the UIS test is the SiC chip 22 (SiC trench MOSFET).

In FIG. 9, in the processing in which the SiC chip 22 fails, the drain voltage of the SiC chip 22 is denoted by V_{DS} (fail), the drain current density is denoted by J_{DS} (fail), and in the processing immediately before the SiC chip 22 fails, the drain voltage of the SiC chip 22 is V_{DS} (last), and the drain current density is J_{DS} (last).

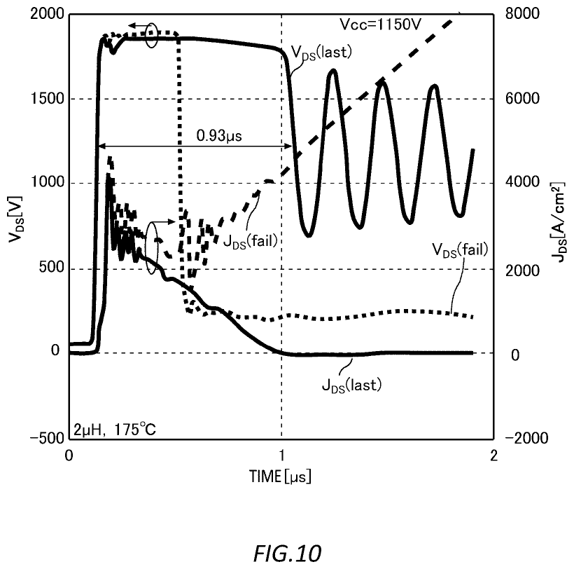

FIG. 10 is a diagram illustrating a measured waveform in the UIS test when the supply voltage Vcc applied to the DUT is 1150 V. Other conditions are similar to those in the example of FIG. 9.

The drain current I_{DS} decreases with a slope of (V_{DS}−Vcc)/L. Therefore, when Vcc is increased, the slope of the drain current I_{DS} becomes small, and the avalanche breakdown period t_{AV} becomes long.

When Vcc=300 V, the drain current could flow up to about 6000 A/cm². On the other hand, when Vcc=1150 V, the drain current could flow only up to about 3000 A/cm². When Vcc=1150 V, the positive feedback operation of the parasitic transistor did not occur until the avalanche breakdown period t_{AV} is 0.93 μs. Furthermore, when the avalanche current further increased, the failure of the SiC chip 22 due to the positive feedback of the parasitic transistor occurred for about 0.4 μs. Therefore, by the control unit 10 setting the turn-off period of the SiC chip 22 to 0.9 μs or less, it is possible to suppress decrease in the withstand capability of the SiC chip 22. That is, by setting the turn-off period of the SiC chip 22 to 0.9 μs or less, it is possible to cause thermal failure before the failure due to the positive feedback operation of the parasitic transistor occurs, and it is possible to prevent the decrease in the withstand capability due to the positive feedback operation of the parasitic transistor.

When Vcc=300 V, the parasitic transistor underwent the positive feedback operation when the avalanche breakdown period t_{AV} is around 0.80 μs, and the SiC chip 22 failed. Therefore, by the control unit 10 setting the turn-off period of the SiC chip 22 to 0.8 μs or less, it is possible to further suppress the decrease in the withstand capability of the SiC chip 22.

The parasitic transistor of each of the plurality of SiC chips 22 may be designed not to be turned on in a region where the current density of the main current (drain current) flowing through the corresponding MOSFET is 6000 A/cm² or less. As described above, by adjusting at least one of the contact resistance R_{c} between the source electrode 50 and the contact region 44 or the resistance Rₛ of the base region 36, it is possible to adjust the current density at which the parasitic transistor starts to be turned on. The contact resistance R_{c} can be adjusted by, for example, at least one of the contact area between the source electrode 50 and the contact region 44 or the doping concentration of the contact region 44. The contact resistance R_{c} is preferably a resistance value of 9.0 mΩcm² or less at the maximum. The contact resistance R_{c} is a value obtained by dividing, by the ratio of the active area, the contact resistance of a case where the entire surface is P+. The resistance Rₛ of the base region 36 can be adjusted by the doping concentration of the base region 36. As an example, the maximum value of the acceptor concentration of the base region 36 may be 1×10¹⁷/cm³ or more, 5×10¹⁷/cm³ or more, or 1×10¹⁸/cm³ or more. In addition, as an example, by setting the maximum value of the doping concentration of the base region 36 to 8×10¹⁷/cm³ or more, it is possible to prevent the positive feedback operation of the parasitic transistor. This is because as the temperature increases, the hole mobility decreases, but the hole concentration increases.

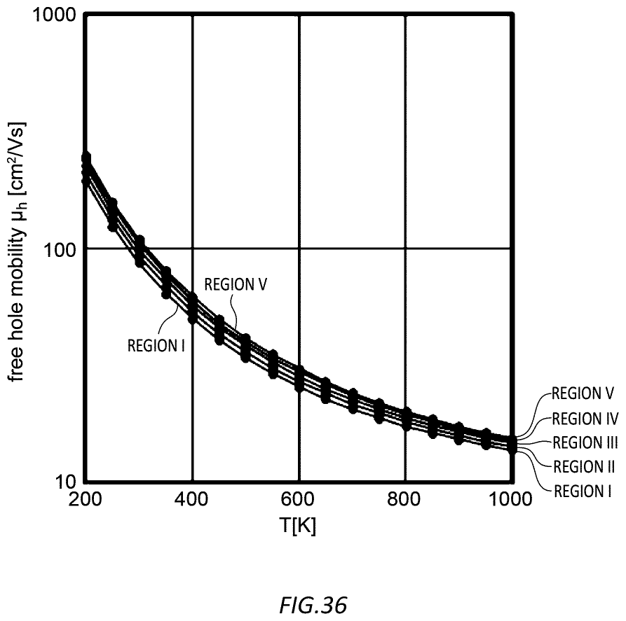

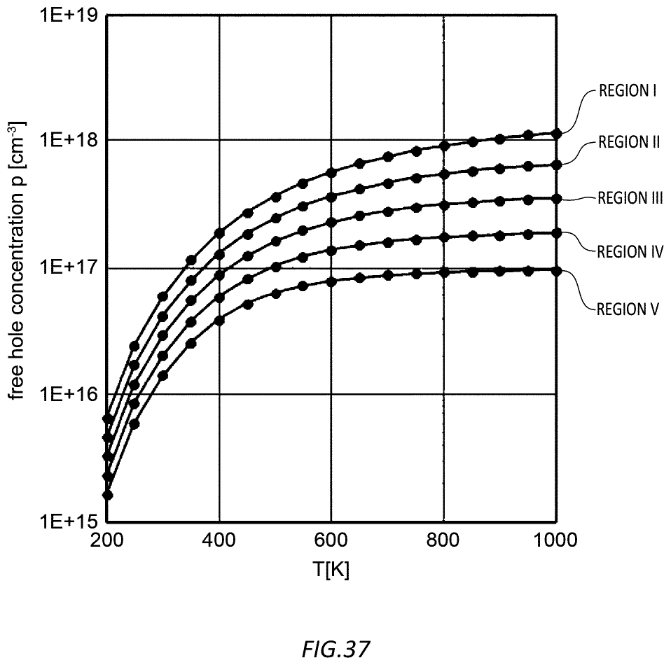

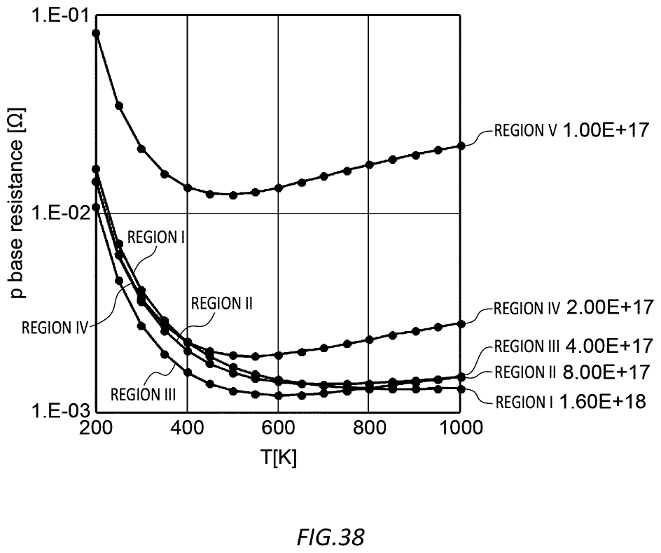

FIG. 36 is a diagram illustrating a hole mobility and temperature characteristics when the acceptor concentration of the base region is changed in the device simulation. FIG. 37 is a diagram illustrating a hole concentration and the temperature characteristics when the acceptor concentration of the base region is changed in the device simulation. FIG. 38 is a diagram illustrating a resistance value and the temperature characteristics of the base region when the acceptor concentration of the base region is changed in the device simulation. The region I is a case where the acceptor concentration of the base region 36 is 1.6×10¹⁸/cm³. The region II is a case where the acceptor concentration of the base region 36 is 8×10¹⁷/cm³. The region III is a case where the acceptor concentration of the base region 36 is 4×10¹⁷/cm³. The region IV is a case where the acceptor concentration of the base region 36 is 2×10¹⁷/cm³. The region Vis a case where the acceptor concentration of the base region 36 is 1×10¹⁷/cm³. The sheet resistance of the base region 36 is proportional to 1/(q μh p) as illustrated in FIG. 36. However, as illustrated in FIG. 38, in the regions III to V of 4×10¹⁷/cm³ or less, the resistance increases at 600 K or more, and on the other hand, in the regions I and II of 8×10¹⁷/cm³ or more, the sheet resistance decreases with the increase of the temperature. When the sheet resistance decreases with temperature, the voltage drop of the base region 36 decreases at high temperature, and the parasitic transistor does not undergo the positive feedback operation.

When the current density of the drain current flowing through each SiC chip 22 exceeds 6000 A/cm², the control unit 10 may set the turn-off time of each SiC chip 22 to the first turn-off time. The decrease in the withstand capability of the SiC chip 22 can be suppressed with such design and control.

The control unit 10 may control the turn-off time of the MOSFET of at least one of the plurality of SiC chips 22 (or all of the SiC chips 22) based on the waveform of the drain current flowing through each SiC chip 22. For example, the control unit 10 may control the turn-off time of the MOSFET of at least one of the plurality of SiC chips 22 based on the slope of the rising edge of the waveform of the drain current. The control unit 10 may set the turn-off time to the first turn-off time when the slope is equal to or larger than a predetermined reference value. In a stage in which the waveform of the drain current is rising, the control unit 10 may estimate the peak value I_{AV} of the drain current based on the rising waveform, and set the turn-off time to the first turn-off time when the estimated peak value is equal to or larger than a predetermined reference value. As a result, the turn-off time of the SiC chip 22 in which the parasitic transistor is likely to be turned on is shortened, so that the decrease in the withstand capability can be suppressed. Alternatively, when the parasitic transistor is likely to be turned on in any of the SiC chips 22, the turn-off times of all of the SiC chips 22 are shortened, so that the decrease in the withstand capability can be suppressed.

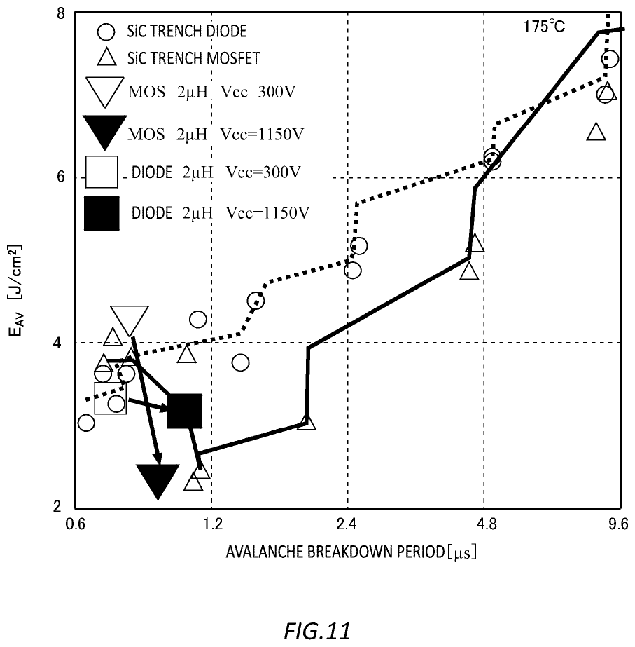

FIG. 11 is a diagram illustrating a change in the avalanche capability when the avalanche breakdown period t_{AV} is changed. In FIG. 11, an example in which the avalanche breakdown period is changed by changing the load inductance L in the UIS test of the SiC trench diode is indicated by a circle mark, and an example in which the avalanche breakdown period is changed by changing the load inductance L in the UIS test of the SiC trench MOSFET is indicated by an upward triangle mark. In addition, the examples described in FIGS. 9 and 10 are each indicated by a downward triangle mark. In addition, the result obtained by performing the same measurement as in FIGS. 9 and 10 on the SiC trench diode is indicated by a square mark.

As described in FIGS. 7 and 8, in the SiC trench MOSFET, when the avalanche breakdown period increases, the parasitic transistor undergoes the positive feedback operation, and the withstand capability decreases. As illustrated in FIG. 11, in the SiC trench MOSFET of a case where the supply voltage Vcc is increased from 300 V to 1150 V, the avalanche breakdown period increases from 0.8 μs to 0.93 μs, and the avalanche capability decreases accordingly. On the other hand, even when the supply voltage Vcc of the SiC trench diode is increased from 300 V to 1150 V, the avalanche capability hardly changes.

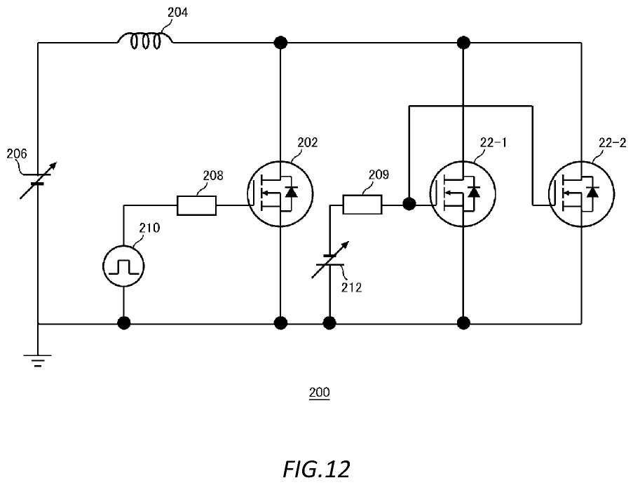

FIG. 12 is a diagram illustrating another example of the measurement circuit 200. In this example, the SiC chip 22 which is a DUT is illustrated divided into two portions. That is, a SiC chip 22-1 and a SiC chip 22-2 are different portions of the same chip.

The SiC chip 22-1 is a local region in which the contact resistance R_{c} is different from that of the SiC chip 22-2 which is a main region. The contact resistance is, for example, a resistance between the contact region 44 provided in one mesa portion sandwiched between two trench portions and the source electrode 50. Alternatively, the resistance is a resistance between one contact region 44 and the source electrode 50 in a top view. The contact resistance R_{c} in the SiC chip 22-2 of this example is 1.8 mΩcm² or 0.18 mΩcm², and the contact resistance R_{c} in the SiC chip 22-1 is 9 mΩcm² to 180 mΩcm².

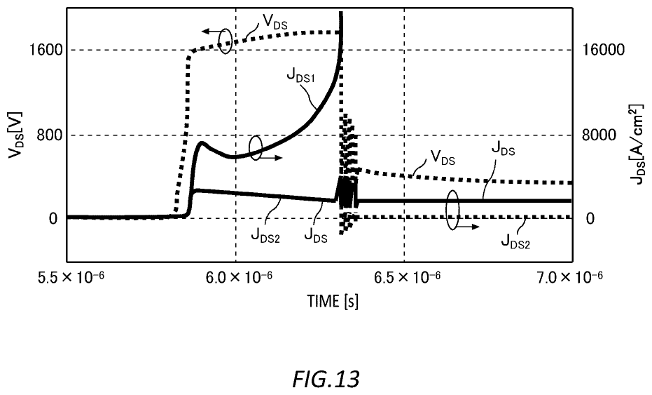

FIG. 13 illustrates drain voltages and drain currents in the SiC chip 22-1 and the SiC chip 22-2. In FIG. 12, the drain current density of the SiC chip 22-1 is denoted by J_{DS1}, the drain current density of the SiC chip 22-2 is denoted by J_{DS2}, and the total drain current density is denoted by J_{Ds}.

When a local region having a high contact resistance R_{c} is present, the current may concentrate in the local region in the vicinity of the end of the turn-off period or the like. For this reason, the local region easily fails, and the withstand capability of the entire chip may decrease.

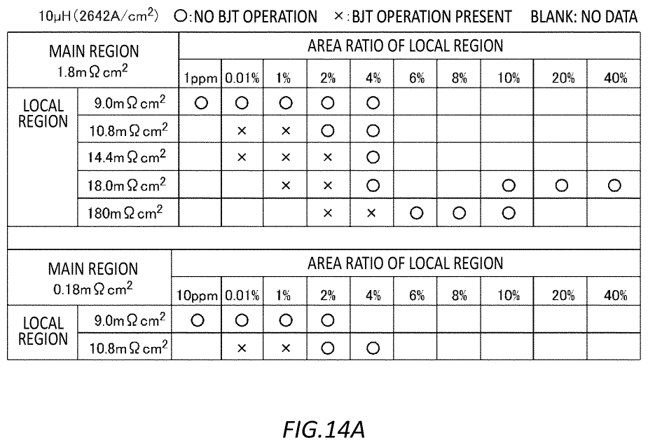

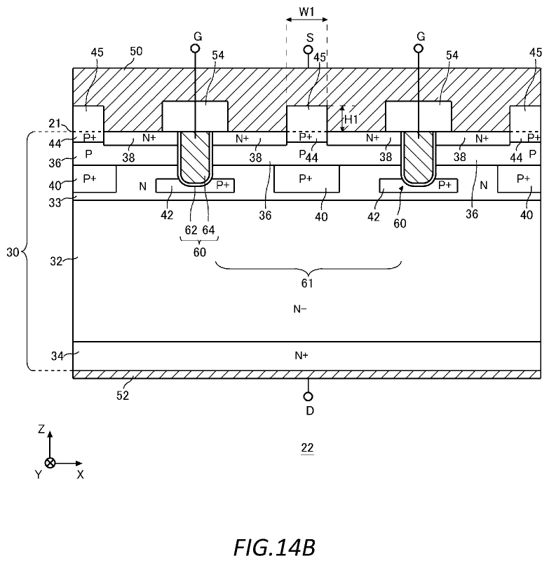

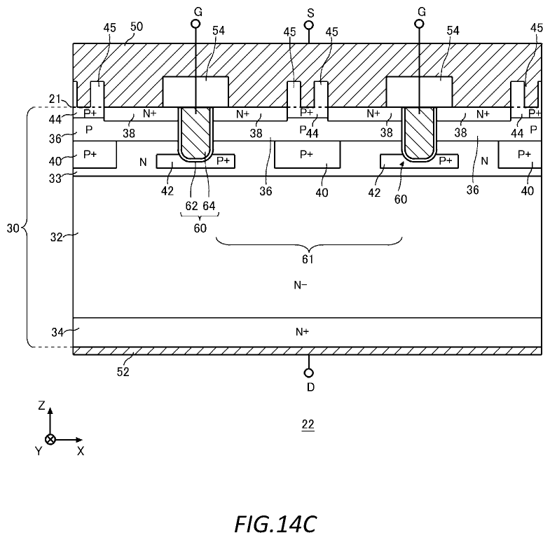

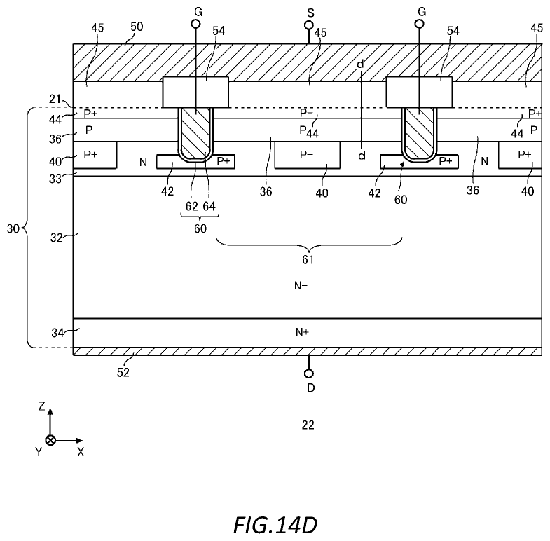

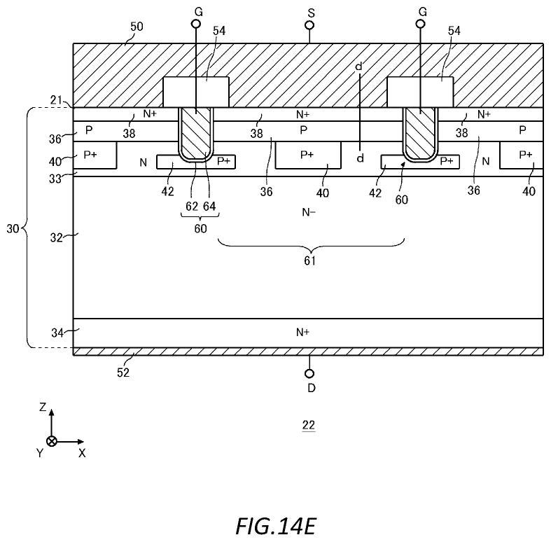

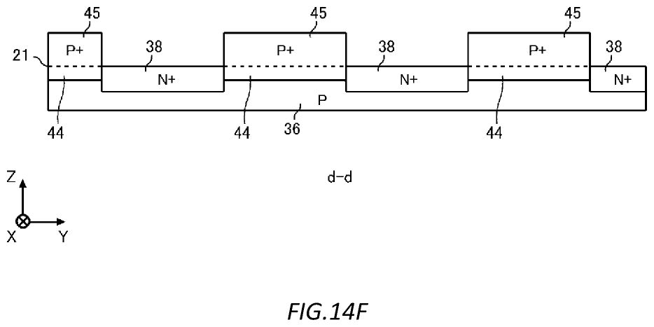

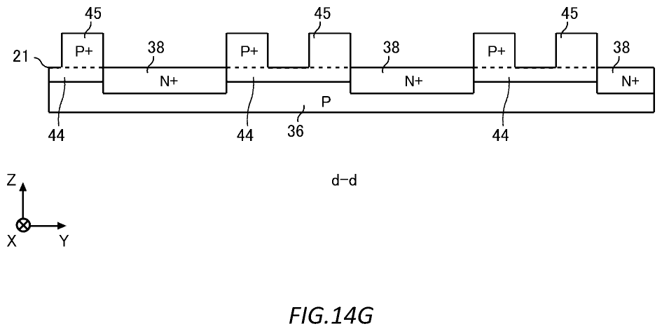

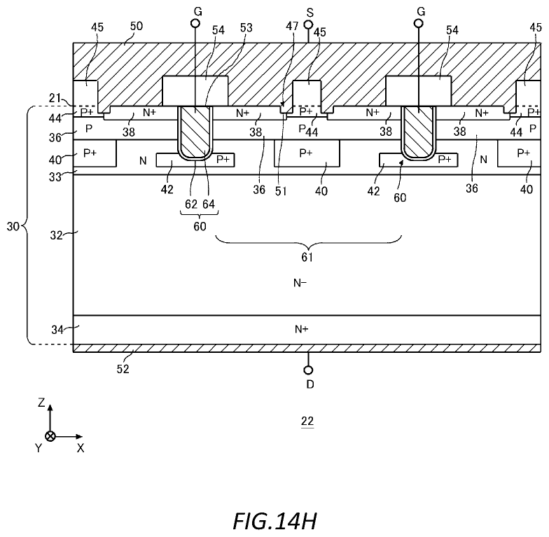

FIG. 14A is a table illustrating whether the parasitic transistor of the SiC chip 22 has operated when a local region is present. In the example of FIG. 14A, the current density of the drain current is 6000 A/cm² or more, and the load inductance L is 10 μH. FIG. 14A illustrates whether the parasitic transistor (BJT) has operated when the contact resistance R_{c} of the local region and the area ratio of the local region have been changed. The contact resistance R_{c} of the local region can be adjusted by, for example, the doping concentration of the contact region 44. The area ratio of the local region is a ratio of the local region, in which the contact resistance R_{c} of the contact region 44 is small, to the entire area where the contact region 44 is provided. In the example of FIG. 14A, the area ratio of the local region is changed from 1 ppm to 40%.

As illustrated in FIG. 14A, when the contact resistance R_{c} of the local region was 9.0 mΩcm², the parasitic transistor did not operate even when the local region is present. In the SiC chip 22, the maximum value of the contact resistance R_{c} may be 9 mΩcm² or less. As a result, the operation of the parasitic transistor of the SiC chip 22 is suppressed, so that the decrease in the withstand capability can be suppressed.

In a case where the contact resistance R_{c} was 10.8 mΩcm², the parasitic transistor operated when the area ratio of the local region was 1% or less. When the area ratio of the local region is small, the current in the small region concentrates, so that the parasitic transistor easily operates. On the other hand, when the area ratio of the local area was 2% or more, the parasitic transistor did not operate. In addition, in a case where the contact resistances R_{c} were 14.4 mΩcm² and 18.0 mΩcm², the parasitic transistor operated when the area ratio of the local region was 2% or less. On the other hand, when the area ratio of the local area was 4% or more, the parasitic transistor did not operate. Furthermore, in a case where the contact resistance R_{c} was 180 mΩcm², the parasitic transistor operated when the area ratio of the local region was 4% or less. On the other hand, when the area ratio of the local area was 6% or more, the parasitic transistor did not operate. For this reason, in the SiC chip 22, the area of the region having the maximum value may be 2% or more when the contact resistance R_{c} is more than 9.0 mΩcm² and 10.8 mΩcm² or less, the area of the region having the maximum value may be 4% or more when the contact resistance R_{c} is more than 10.8 mΩcm² and 18.0 mΩcm² or less, and the area of the region having the maximum value may be 6% or more when the contact resistance R_{c} is more than 18.0 mΩcm² and 180 mΩcm² or less. The BJT failure depends not on the contact resistance R_{c} of the main region but on the area ratio of the local region and the contact resistance R_{c} thereof.

FIG. 14B is a diagram illustrating another example of a cross section of the SiC chip 22. The SiC chip 22 of this example is different from the other examples described in the present specification in the structure of the contact region 44. The structure other than the contact region 44 is similar to any aspect described in the present specification. In the SiC chip 22 of this example, the contact resistance R_{c} is reduced by changing the structure of the contact region 44. As a result, the operation of the parasitic transistor of the SiC chip 22 is suppressed, so that the decrease in the withstand capability can be suppressed.

In this example, a surface of the semiconductor substrate 30 on which the source electrode 50 is provided is defined as an upper surface 21. Two axes parallel to the upper surface 21 are defined as an X axis and a Y axis. The X axis and the Y axis are orthogonal to each other. An axis perpendicular to the upper surface 21 is defined as a Z axis. The Z axis is an axis indicating the depth direction of the semiconductor substrate 30. An X axis direction is an example of a first direction, and a Y axis direction is an example of a second direction.

In this example, a plurality of gate trench portions 60 is disposed at predetermined intervals along the X axis direction. Each gate trench portion 60 is provided from the upper surface 21 of the semiconductor substrate 30 to the inside of the semiconductor substrate 30. The region of the semiconductor substrate 30 sandwiched between two gate trench portions 60 in the X axis direction is referred to as a mesa portion 61.

As described in FIG. 3 or the like, the source region 38 and the contact region 44 are provided in the mesa portion 61 on the upper surface 21. The source region 38 is a region of the first conductivity type (the N+ type in this example) provided in contact with the gate trench portion 60 on the upper surface 21. The contact region 44 is a region of the second conductivity type (the P+ type in this example) provided on the upper surface 21.

The contact region 44 of this example has a protrusion 45 protruding upward from the source region 38. The upper surface and the side surface of the protrusion 45 are in contact with the source electrode 50. By providing the protrusion 45, the contact area between the source electrode 50 and the contact region 44 can be increased, and a variation in the contact resistance R_{c} can be reduced.

The width of the contact region 44 in the X axis direction is defined as a first width W1. The first width W1 is the maximum width of the contact region 44 in the direction. A length by which the protrusion 45 protrudes from the upper end of the source region 38 in the Z axis direction is defined as a protrusion length H1. The protrusion length H1 is a distance between the upper end of the protrusion 45 and the upper end of the source region 38 in the Z axis direction.

The protrusion length H1 may be the first width W1 or more. By increasing the protrusion length H1, the contact area between the source electrode 50 and the contact region 44 can be increased, and the contact resistance R_{c} can be reduced. The protrusion length H1 may be 1.5 times or more, or 2 times or more the first width W1.

In the example of FIG. 14B, the width of protrusion 45 in the X axis direction is same as the first width W1 of the contact region 44. In another example, the width of the protrusion 45 may be smaller than the first width W1. On the upper surface 21 of the semiconductor substrate 30, the protrusion 45 may be formed by etching a region other than the protrusion 45 to a predetermined depth. After the protrusion 45 is formed, the gate trench portion 60 may be formed.

FIG. 14C is a diagram illustrating another example of the cross section of the SiC chip 22. The SiC chip 22 of this example is different from the example of FIG. 14B in the structure of the protrusion 45. Other structures are similar to those in the example of FIG. 14B.

In the SiC chip 22 of this example, the contact region 44 has a plurality of protrusions 45 in one of one or more mesa portions 61. By providing the plurality of protrusions 45, the contact area between the source electrode 50 and the contact region 44 can be further increased. One contact region 44 may have two protrusions 45, or three or more protrusions 45.

The plurality of protrusions 45 of this example is arranged in the X axis direction. The upper end of the contact region 44 between two protrusions 45 may be the same as the position of the upper end of the source region 38, may be disposed above the upper end of the source region 38, or may be disposed below the upper end of the source region 38.

FIGS. 14D and 14E are diagrams illustrating other examples of the cross section of the SiC chip 22. In the example of FIGS. 14D and 14E, the contact region 44 and the source region 38 are alternately disposed along the Y axis direction. FIG. 14D illustrates an XZ cross section passing through the contact region 44, and FIG. 14E illustrates an XZ cross section passing through the source region 38. Each of the contact region 44 and the source region 38 of this example is provided entirely between two gate trench portions 60 in the X axis direction.

As illustrated in FIG. 14D, the contact region 44 of this example also has the protrusion 45. In the X axis direction, the width of the protrusion 45 may be equal to the width of the contact region 44 or smaller than the width of the contact region 44. The protrusion 45 may be in contact with or apart from the interlayer dielectric film 54 covering the gate trench portion 60.

FIG. 14F is a diagram illustrating an example of a YZ cross section passing through a d-d line in FIGS. 14D and 14E. As illustrated in FIG. 14F, each of the contact regions 44 discretely disposed in the Y axis direction has the protrusion 45. In this example, the plurality of protrusions 45 is arranged in the Y axis direction. In this example, each contact region 44 has one protrusion 45. In the Y axis direction, the width of the protrusion 45 may be equal to the width of the contact region 44 or smaller than the width of the contact region 44.

In this example, the width of the contact region 44 in the Y axis direction is defined as the first width W1. The protrusion length H1 of the protrusion 45 may be equal to or larger than the first width W1. The protrusion length H1 may be 1.5 times or more, or 2 times or more the first width W1.

FIG. 14G is a diagram illustrating another example of the YZ cross section passing through the d-d line. The SiC chip 22 of this example is different from the example of FIG. 14F in the structure of the protrusion 45. Other structures are similar to those in the example of FIG. 14F.

In the SiC chip 22 of this example, one contact region 44 has a plurality of protrusions 45 arranged in the Y axis direction. The upper end of the contact region 44 between two protrusions 45 may be the same as the position of the upper end of the source region 38, may be disposed above the upper end of the source region 38, or may be disposed below the upper end of the source region 38. By providing the plurality of protrusions 45, the contact area between the source electrode 50 and the contact region 44 can be further increased.

FIG. 14H is a diagram illustrating another example of the cross section of the SiC chip 22. The SiC chip 22 of this example further includes a contact trench portion 47 as compared with other examples described in the present specification. Other structures are similar to those in any of the examples described herein.

The source region 38 and the contact region 44 are in contact with each other in the X axis direction or the Y axis direction. The contact trench portion 47 of this example is a groove portion including a boundary position between the source region 38 and the contact region 44 and having a portion disposed in each region of the source region 38 and the contact region 44. The contact region 44 is exposed on the side wall of the contact trench portion 47, and the inside of the contact trench portion 47 is filled with the source electrode 50. As a result, the contact area between the source electrode 50 and the contact region 44 can be further increased.

In another example, the contact trench portion 47 may not be provided inside the contact region 44. Also in this case, the contact trench portion 47 includes the boundary position between the source region 38 and the contact region 44 and has a portion disposed in the source region 38. In this example, the upper end 51 of the source region 38 at a position at which the source region is in contact with the contact region 44 is disposed below the upper end 53 of the corresponding one of the one or more gate trench portions 60. The contact region 44 is exposed on the side wall of the contact trench portion 47, and the inside of the contact trench portion 47 is filled with the source electrode 50. As a result, the contact area between the source electrode 50 and the contact region 44 can be further increased.

The contact trench portion 47 of this example is disposed at the boundary position between the source region 38 and the contact region 44 adjacent to each other in the X axis direction. The contact trench portion 47 may be provided to extend in the Y axis direction. That is, the length of the contact trench portion 47 in the Y axis direction may be larger than the length in the X axis direction.

In another example, the contact trench portion 47 may be disposed at the boundary position between the source region 38 and the contact region 44 adjacent to each other in the Y axis direction as illustrated in FIG. 14F. In this case, the contact trench portion 47 may be provided to extend in the X axis direction. That is, the length of the contact trench portion 47 in the X axis direction may be larger than the length in the Y axis direction.

### (Discussion of Load Inductance Dependency of Avalanche Capability and Failure Mechanisms in SiC Trench MOSFET)

In the following, the discussion of the load inductance dependency of the avalanche capability and failure mechanisms in the SiC trench MOSFET will be described. The following discussion does not limit the scope of the present invention beyond what is described in the claims. In the following discussion, the SiC trench MOSFET described above may be simply referred to as a MOSFET, and the SiC trench diode may be simply referred to as a diode.

A metal oxide semiconductor field effect transistor (MOSFET) using 4H—SiC has various advantages such as high-speed switching, low conduction loss, and high-temperature operation as compared with a currently mainstream insulated gate bipolar transistor (IGBT) using silicon (Si). Therefore, the SiC-MOSFET has started to be used in various applications such as automobiles, railways, and renewable energy systems.

In recent years, the density of killer defects present in SiC wafer crystals has been reduced, and the non-defective product rate of SiC devices has been improved. However, the chip size of the SiC element can be increased only up to about 1 cm² in order to maintain a high non-defective product rate. Therefore, in a power module having a large current rating, it is necessary to connect SiC chips in parallel. One of concerns in this case is that the turn-off time of a specific chip is delayed due to a low gate threshold voltage (Vₜₕ), and as a result, the total current of the module concentrates on the chip to cause avalanche breakdown. When the avalanche capability is insufficient, the element may fail. In the latest SiC module, in order to reduce the switching loss, operation is performed at a high dI_{D}/dt (I_{D}: drain current), and a high surge voltage is generated, so that attention is required. For example, under the operating conditions of a parasitic loop inductance of 100 nH and dI_{D}/dt at the time of turn-off of 5 kA/μs, a surge voltage as large as 500 V is generated, which causes avalanche breakdown and increases the risk of failure. For this reason, the SiC MOSFET for cutting-edge modules needs to have a high avalanche capability.

Many studies have been made on avalanche capability by an unclamped inductive switching (UIS) test of SiC-MOSFETs. Some have examined the dependency of avalanche capability on load inductance in the UIS test. As described above, when current concentrates on a specific chip at the time of turn-off, it is necessary to have such a design that failure does not occur even at the time of conduction of avalanche current which is several times the rated current of one element in parallel. In general, the parasitic inductance of the module is as low as 1 μH or less, and thus in practical use of the SiC MOSFET, it is extremely important to investigate the avalanche current that does not cause failure even with such a low inductance, but such a report has not been found.

On the other hand, it is hard to say that the failure mechanisms in the UIS test are completely elucidated. One of the failure mechanisms is that when large current flows under a high voltage, the lattice temperature increases due to Joule heat, and failure occurs at a certain critical temperature (A. Konstantinov, F. Allerstam, H. Pham, G. Park, K. S. Park, D. Waible, and T. Neyer, “Critical temperature and failure mechanism of SiC Schottky rectifiers in Unclamped Inductive Switching (UIS)”, Proceedings of the 2020 32nd International Symposium on Power Semiconductor Devices and ICs (ISPSD), 2020, pp. 158-161). In addition, Ren et al. have studied the possibility of a parasitic bipolar junction transistor (BJT) operation as an avalanche breakdown mode of a SiC planar MOSFET at a load inductance of 75 μH to 10 mH (N. Ren, K. L. Wang, “Failure Mechanism Analysis of SiC MOSFETs in Unclamped Inductive Switching Conditions”, Proc. 31st International Symposium on Power Semiconductor Devices & ICs, 2019, pp. 183-186). Furthermore, Hu et al. report that when the load inductance was increased from 1.2 mH to 9.5 mH, the avalanche energy leading to avalanche breakdown increased, and the avalanche current decreased (J. Hu, O. Alatise, J. A. O. Gonzalez, R. Bonyadi, L. Ran and P. A. Mawby, “The Effect of Electrothermal Nonuniformities on Parallel Connected SiC Power Devices Under Unclamped and Clamped Inductive Switching”, IEEE Transactions on Power Electronics, Vol. 31, No. 6, 2016, pp. 4526-4535). This is because when the load inductance is high, the avalanche current is small, thus a variation between the cells of the avalanche current is small, and the operation of the parasitic BJT constituted by n+ source/p base/n. JFT on the element surface is suppressed. Fayyaz et al. propose a failure mechanism in which a high lattice temperature under an avalanche breakdown condition causes a decrease in a gate threshold voltage (Vₜₕ), and a MOS channel current flows thereby, so that the lattice temperature is further increased to cause failure (A. Fayyaz, A. Castellazzi, G. Romano, M. Riccio, A. Irace, J. Urresti and N. Wright, “UIS failure mechanism of SiC power MOSFETs”, IEEE 4th Workshop on Wide Bandgap Power Devices and Applications (WiPDA), 2016, pp. 118-122). However, Nida et al. investigated the influence of the gate negative bias at the time of turn-off on the avalanche capability, and reported that the avalanche capability is not improved even when the gate negative bias is deepened (S. Nida, T. Ziemann, B. Kakarla, and U. Grossner, “Effect of Negative Gate Bias on Single Pulse Avalanche Ruggedness of 1.2 kV Silicon Carbide MOSFETs”, Materials Science Forum, Vol. 924, 2018, pp. 735-738). Thus, the avalanche breakdown mechanism has not yet been clarified.

From the above background, the purpose of this discussion is as follows. (1) To show superiority of parallel connection of SiC-MOSFETs over Si-IGBTs. An avalanche allowable current at 1 μH (a minimum load inductance verifiable in this discussion) close to an actual parasitic inductance value of the power module is measured, and the maximum number of elements which can be connected in parallel in the module is obtained. (2) To clarify the avalanche breakdown mechanism. In order to verify the influence of the parasitic n-p-n BJT in the vicinity of the element surface, a SiC trench diode in which the n+ source region is intentionally removed from the SiC trench MOSFET was manufactured and evaluated. The avalanche capability (current and energy) of the SiC trench MOSFET and the SiC trench diode is investigated and compared in a wide range of 1 μH to 5 mH, and the avalanche breakdown mechanism is verified by device simulation.

### Element Structure and Avalanche Capability Evaluation Method

The evaluation elements (Device Under Test: DUT) in this discussion are a SiC trench MOSFET, a SiC trench diode, and a Si-IGBT. The voltage rating of these DUTs was 1.2 kV, and the current rating was similar. The cross-sectional views of the SiC trench MOSFET and the SiC trench diode are shown in FIGS. 3 and 4.

The SiC trench MOSFET is designed such that a p-well of at the trench bottom protects the gate oxide film from high electric fields during reverse bias. In addition, a junction field effect transistor (JFET) region including a p base/n region/trench-bottom p-well is optimized to simultaneously satisfy a low on-resistance (low Rₒₙ·A), a low drain-source leakage current, and a high breakdown voltage. Furthermore, Rₒₙ· A is kept low by optimizing the gate oxidation process while preventing erroneous turn-on caused by electrical noise with a high Vₜₕ of about 5 V. A breakdown voltage (BV_{DSS}) at the off-state and a leakage current of 1 mA between the drain and the source is 1540 V as a representative value of 25° C. The SiC trench diode has the same structure and dimensions as the SiC trench MOSFET except that the n+ source region is not present.

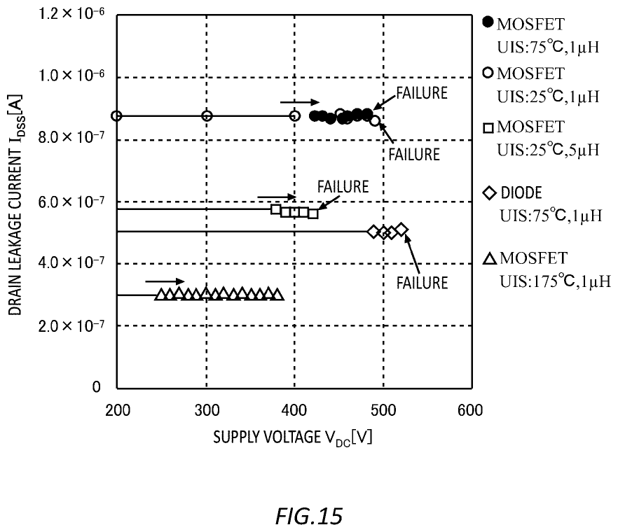

The Si-IGBT to be compared incorporates cutting-edge device technologies such as a trench gate structure, a field stop layer by a thin wafer, and an optimized surface design, and has a structure exhibiting an excellent tradeoff between on-voltage and turn-off loss. FIG. 5 illustrates a UIS circuit in this discussion. The measurement was performed at a temperature of 25° C. to 175° C. The UIS circuit includes a DC voltage power supply, a load inductance in a range of 1 μH to 5 mH, a 1.2 kV SiC-DUT in which gate and source terminals are short-circuited, and a gate driving MOSFET. In order to cause avalanche breakdown only in the 1.2 kV SiC-DUT, the gate driving MOSFET is set to a high breakdown voltage class of 3.3 kV, and the active region is set to about 6 times that of the 1.2 kV SiC-DUT so that a sufficiently high drain current can be obtained in the low inductance region. While gradually increasing the voltage of the DC power supply, the UIS test is repeatedly performed until failure of the element occurs. When there is element damage before the failure, accurate withstand capability evaluation cannot be performed, but as illustrated in FIG. 15, a leakage current (Ipss) between the drain and source at 1200 V remains almost constant at the time of UIS measurement before the failure, and it is checked that there is no device damage before the device failure. The peak of the drain current density in the UIS test at the last before the element failure is referred to as the avalanche allowable current density J_{AV} [A/cm²], and a value obtained by integrating, over the avalanche period, the product of the drain voltage and the drain current at each time during the avalanche breakdown period and dividing the result by the active area is referred to as the avalanche holding energy E_{AV} [J/cm²]. These J_{AV} and E_{AV} are referred to as the avalanche capability.

### (Load Inductance Dependency of Avalanche Capability of SiC Trench MOSFET)

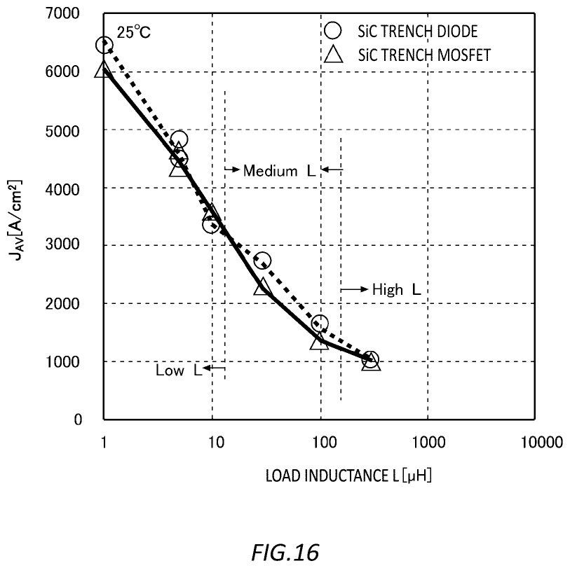

FIGS. 7, 8, 16, and 17 illustrate the load inductance dependency of the avalanche allowable current density J_{AV} and the avalanche holding energy E_{AV}. The load inductance is changed in the range of 1 μH to 5 mH, and the temperature is changed in the range of 25° C. to 175° C. At a load inductance of 1 μH close to the parasitic inductance of the power module, J_{AV} of the SiC trench MOSFET was 6000 AA/cm² or more in the temperature range of 25° C. to 175° C. This value is as high as about 3.3 times J_{AV} at 175° C. in the Si-IGBT. When the chips having the same size are connected in parallel in the power module, a current value which may be concentrated on one chip at turn-off becomes the number-of-parallel connections times the rated current of each chip. Therefore, it can be said that the SiC trench MOSFET having a high avalanche allowable current J_{AV} can connect more chips in parallel than the Si-IGBT. This makes it possible to realize a power module of the same current rating with a larger number of small-area chips, leading to improvement of the non-defective product rate and reduction of the SiC module cost for the SiC element in which the killer defect density in the crystal has not yet been sufficiently reduced.

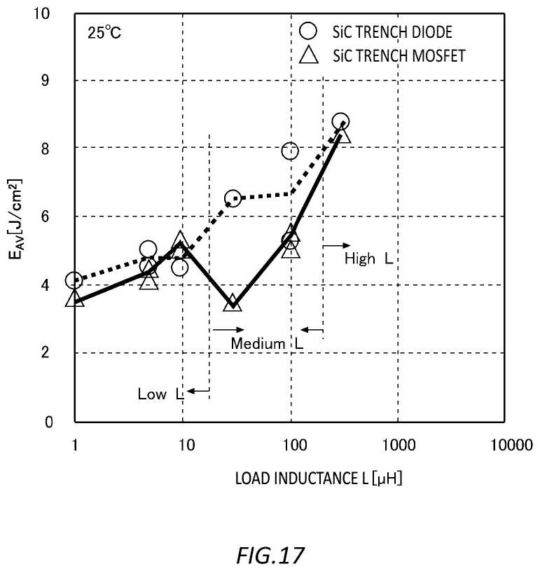

Next, in the SiC trench diode, inherent characteristics are exhibited such that as the load inductance increases, the avalanche allowable current J_{AV} monotonously decreases, and the avalanche holding energy E_{AV} monotonously increases. In the avalanche breakdown mechanism of the SiC trench diode, it is considered that an excessive temperature rise is caused due to power consumption at the time of avalanche breakdown, and failure occurs at a certain critical temperature. In this model, the monotonic increase in E_{AV} of the SiC diode seen in FIGS. 8 and 17 is described as follows.

At a low load inductance, the avalanche period t_{AV} is as substantially short as 1 μs or less, and the generated heat is adiabatic in the drift layer. On the other hand, at a high load inductance, the avalanche period t_{AV} is as long as several 10 μs, and the volume heated by thermal diffusion is increased. Therefore, when the temperature at the time of failure is the same, more energy is required as the load inductance increases. At this time, a thermal diffusion length Lₜ is expressed such that

Lₜ=b(Dt_{AV})^{1/2}

(b is a numerical coefficient, and D is a thermal diffusion constant), and E_{AV} is proportional to Lₜ, so when the SiC trench diode failure mechanism is the above, E_{AV} increases linearly with respect to t_{AV}^{1/2}.

The power density in the local region of the MOSFET easily becomes higher than the power density of the diode. A difference in power density becomes a difference in temperature rise rate. As described above, when the internal temperature of the semiconductor substrate 30 reaches a critical temperature, the failure of the parasitic transistor (BJT) occurs. The critical temperature is a temperature at which the sheet resistance of the base region 36 begins to increase, and the BJT failure is failure due to BJT operation and subsequent positive feedback of BJT electron current density.

In a region where the load inductance is relatively low in the Medium-L region, such as a region where the load inductance is about 10 μH, the avalanche period is relatively short. Therefore, a difference in power density between the local region of the MOSFET and the diode is easily reflected in the temperature. As a result, in the local region of the MOSFET, the avalanche capability is lower than that of the diode.

In a region where the load inductance is relatively high in the Medium-L region, such as a region where the load inductance is about 100 μH, the avalanche period is relatively long, and thus heat is diffused outward from the local region of the MOSFET. As a result, the power density is hardly reflected in the temperature, and heat is equalized. For this reason, a larger power density is required for the local region of the MOSFET to reach the critical temperature, and the avalanche capability of the MOSFET approaches the characteristics of the diode as illustrated in FIG. 17.

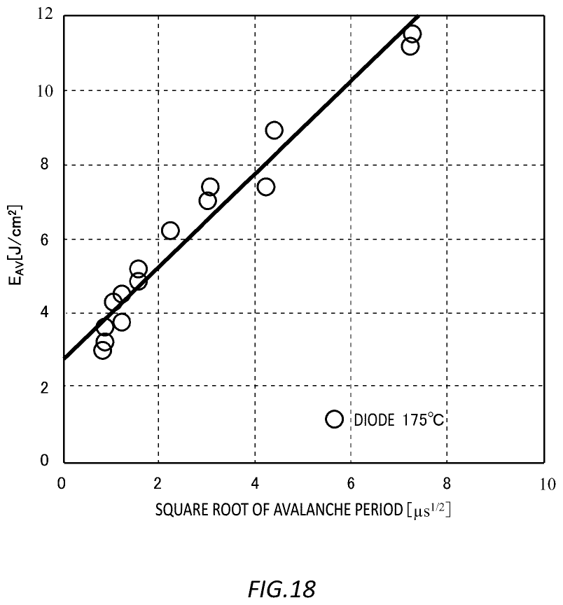

FIG. 18 illustrates a relationship between E_{AV} and the square root t_{AV}^{1/2} of the avalanche duration in the SiC trench diode. This relationship is also almost linear, and is considered to support the above mechanism that heat diffusion occurs due to high load inductance.

On the other hand, in the SiC trench MOSFET, characteristics are exhibited such that the avalanche capability is discontinuous with respect to the load inductance. When the load inductance is increased from 5 μH to 10 μH at 175° C. (at 25° C., from 10 μH to 30 μH), the avalanche capability of the SiC trench MOSFET rapidly decreases as compared with the diode. When the load inductance is increased in a range of 10 μH to 100 μH at 175° C. (30 μH to 100 μH at 25° C.), a difference in E_{AV} from the diode decreases while E_{AV} increases, and the avalanche capability matches with the withstand capability of the diode again at 300 μH or more. In the next and subsequent paragraphs, such a unique load inductance dependency of the avalanche capability of SiC trench MOSFET will be analyzed.

For convenience, the range of the load inductance is defined as “Low-L region”, “Medium-L region”, and “High-L region” as illustrated in FIGS. 7, 8, 16, and 17. The Medium-L region is a region where the SiC trench MOSFET has a lower avalanche capability than that of the SiC trench diode. The Low-L region and the High-L region are defined as a region having an inductance lower than that of the Medium-L region and a region having an inductance higher than that, respectively, and are regions in which the MOSFET has the avalanche capability similar to that of the diode.

### (Avalanche Breakdown Mechanism of SiC Trench MOSFET)

### (Analysis of Measured Waveform)

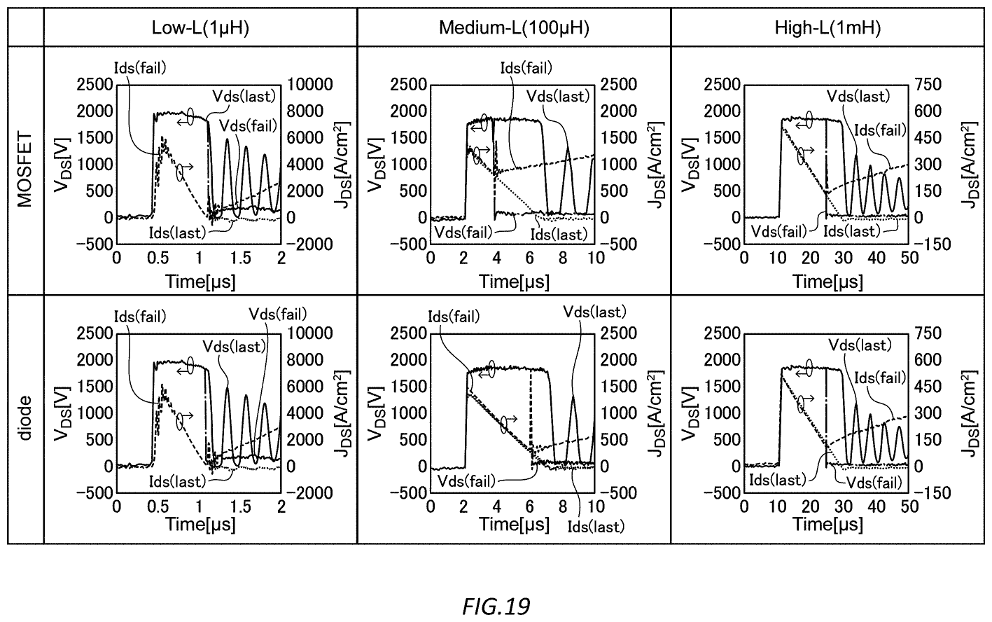

FIG. 19 is a graph in which actual measured waveforms of the UIS test at the time of failure and at the last before the failure in the SiC trench MOSFET and the diode in each region of Low-L to High-L are superimposed. It can be seen from the drawing that the drain-source voltage (V_{DS}) waveform varies depending on the load inductance region. In the Low-L region, V_{DS} is maximized at the peak of the drain current density (J_{DS}) at the initial stage of the avalanche breakdown, whereas in the Medium-L and High-L regions, V_{DS} is maximized after passing the peak of J_{Ds}. The V_{DS} waveform was analyzed as follows to finally estimate the lattice temperature during the avalanche breakdown period. Assuming that the donor concentration uniform over the entire drift layer is N_{D}, the electron density is n(t), and the maximum electric field at the n-drift layer/p base layer junction interface is Eₘ(t), V_{DS} is expressed by the following expression in a simple one-dimensional model.

$$\begin{matrix}[ Mathematical formula 1 ] & \\ {V}_{D S} ( t ) = {\int }_{0}^{d} E ( z , t ) dz = {E}_{m} ( t ) d - \frac{q}{2 {ε}_{s}} \{ {N}_{D} — n ( t ) \} {d}^{2} & Expression 1\end{matrix}$$

Herein, E(z,t) is an electric field distribution in a depth z direction at time t, d is the thickness of the n-drift layer, q is the charge element amount, and εₛ is the dielectric constant of SiC. Since Eₘ(t) in the above expression is determined by the lattice temperature, and n(t) is proportional to the drain current density J_{DS}, V_{DS} eventually becomes a function of the lattice temperature and the drain current density J_{DS}. When the relationship between J_{DS} and V_{DS} under a constant temperature condition is known, the lattice temperature during the avalanche breakdown period can be estimated from the actual measured V_{DS} waveform.

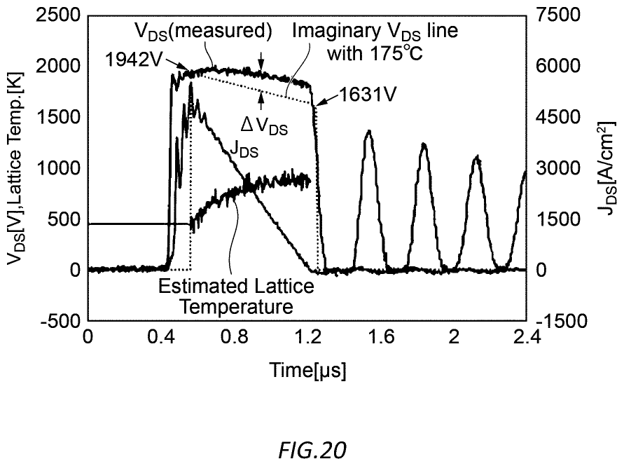

A procedure will be described which estimates the lattice temperature on the basis of the actual measured waveform of the UIS test in FIG. 20. First, an imaginary V_{DS} line at a lattice temperature of 175° C. is obtained by connecting two points of V_{DS} (1942 V in the drawing) at the maximum J_{DS} and a breakdown voltage (1631 V in the drawing) at 175° C. and I_{DSS}=1 mA at the end of avalanche breakdown. In FIG. 20, since J_{DS} decreases linearly with time, the imaginary V_{DS} line at 175° C. connects the above two points with a straight line. A deviation ΔV_{DS} between the V_{DS} measured waveform and the imaginary line at each time during the avalanche breakdown period indicates an increase in temperature from 175° C. It is known that the breakdown voltage with respect to the junction temperature of the SiC-MOSFET exhibits a linear relationship.

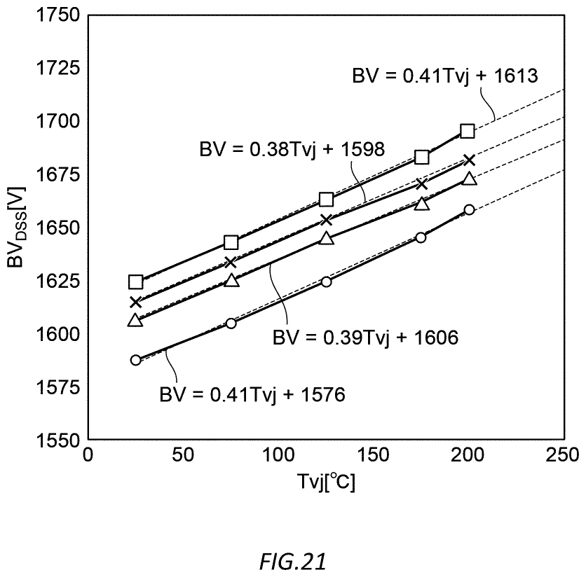

When the temperature dependency of the breakdown voltage of the SiC trench MOSFET used in this discussion is plotted in FIG. 21, the average value of the slopes is 0.40 V/K. By converting ΔV_{DS} into a temperature on the basis of this value, the lattice temperature can be estimated.

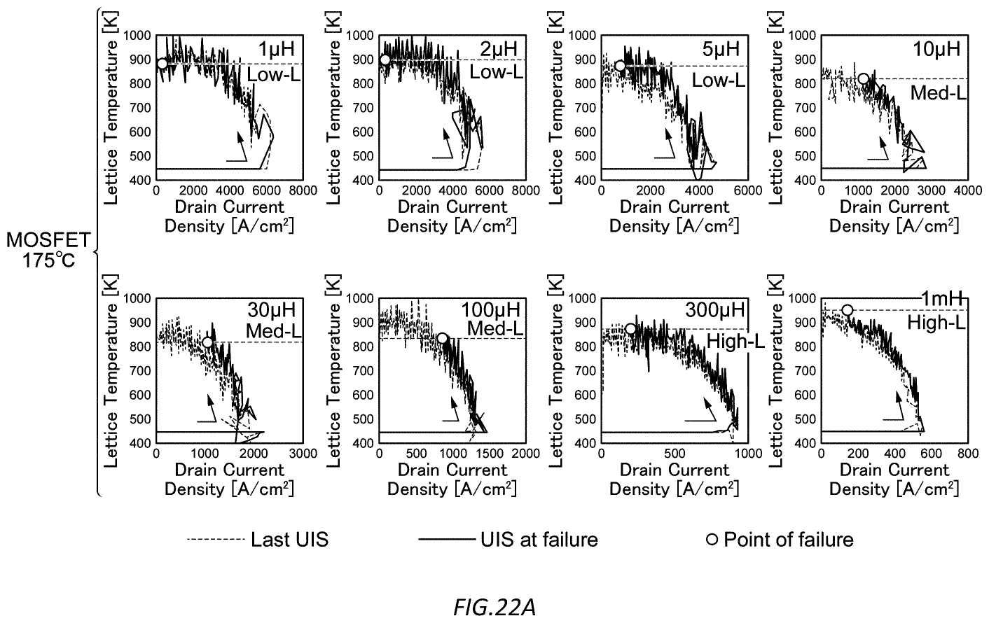

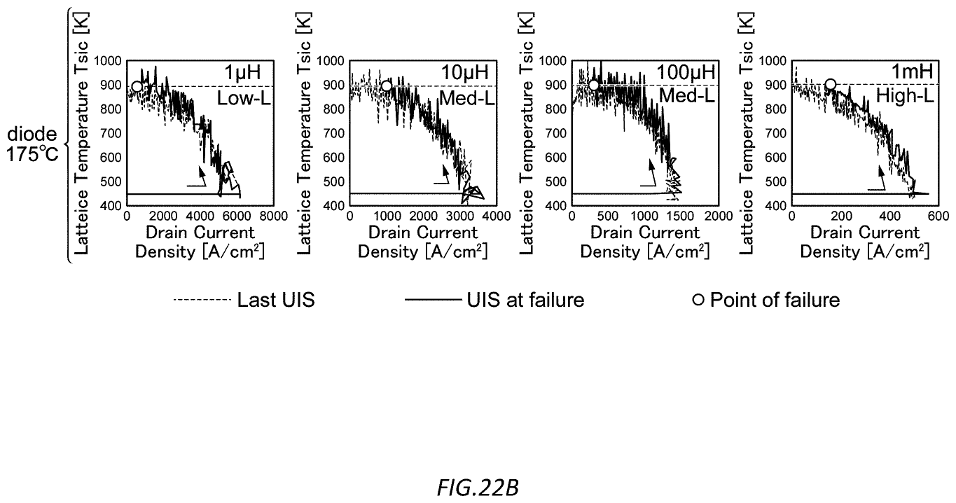

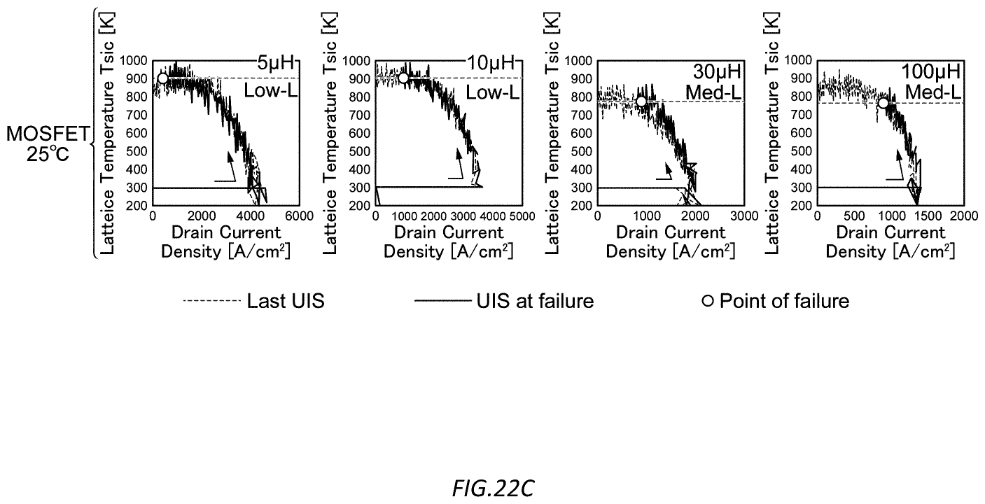

FIGS. 22A, 22B, and 22C illustrate trajectories of the estimated lattice temperature and J_{DS} at the last before the failure and at the time of failure in the UIS test. In the SiC trench MOSFET having the Low-L and High-L regions of the load inductance and the SiC trench diode having the entire range of the load inductance, the estimated lattice temperature at the time of failure was about 900 K. This temperature is close to an Al (aluminum) melting point of 933 K.

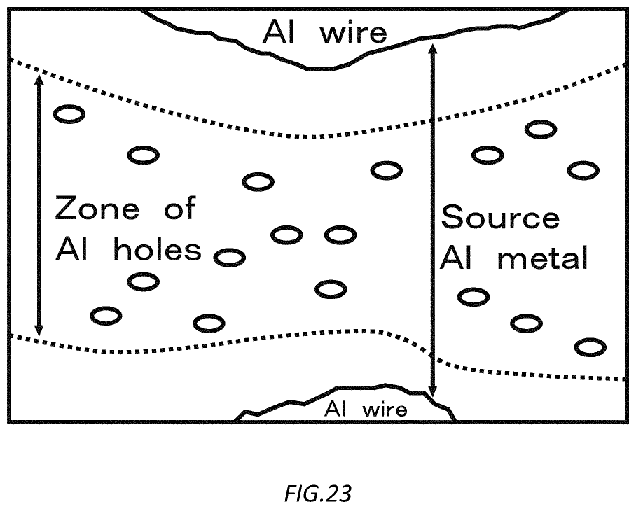

FIG. 23 is a schematic view of a secondary electron microscope image of the source Al metal surface of the SiC trench MOSFET in which avalanche breakdown occurs at 175° C. and 1 mH, and it has been checked that a large number of holes are formed in the Al metal. From the above, it is considered that these element failures relate to melting of Al as the source metal. On the other hand, the SiC trench MOSFET in the Medium-L region fails at about 800 K as illustrated in FIGS. 22A and 22C, and a failure mechanism different from the failure mechanism relating to Al melting is presumed. In this regard, the following avalanche breakdown mechanism reported in the past is verified in the following section.

(1) Parasitic n-p-n BJT Operation

### (2) Vₜₕ Decrease Due to Rise in Lattice Temperature and MOS Channel Current Associated Therewith

### (Failure Mechanism Due to Parasitic BJT Operation and Positive Feedback)

The parasitic BJT operation is caused when a large avalanche hole current Iₕ flows through the p base layer and the voltage drop ΔV between the p base and the source metal exceeds the built-in potential V_{bi} of the p base/n+ source junction, and is expressed by the following expression.

$$\begin{matrix}[ Mathematical formula 2 ] & \\ Δ V = ( {R}_{C} + {R}_{S} ) {I}_{h} \underline{>} {V}_{b i} & Expression ( 2 )\end{matrix}$$

wherein, R_{c} is a contact resistance between the surface p base and the source metal, Rₛ is a resistance of the p base, and Rₛ is expressed by the following expression.

$$\begin{matrix}\{ Mathematical formula 3 ] & \\ {R}_{S} = \frac{1}{q {μ}_{h} ( T ) p ( T )} \frac{L}{A} & Expression ( 3 )\end{matrix}$$

wherein, L is a distance by which a hole passes along the n+ source region and A is the cross section of the p base through which the hole passes. μₕ(T) and p(T) are hole mobility and p base hole concentration, respectively, and both are functions of the lattice temperature T. μₕ(T) is based on the Masetti bulk mobility model and is expressed as follows.

$$\begin{matrix}[ Mathematical formula 4 ] & \\ {μ}_{h} ( T ) = {μ}_{min 1} + \frac{{μ}_{c o n s t} ( T ) - {μ}_{m i n 2}}{1 + {( \frac{{N}_{A}}{{N}_{r e f}} )}^{γ ( T )}} & Expression ( 4 )\end{matrix}$$

wherein, N_{A} is a p base acceptor concentration, and Ξ_{const}(T) is described by the following expression.

$${μ}_{const} ( T ) = {{μ}_{max} ( \frac{T}{300} )}^{- Exponent} \qquad Expression ( 5 )$$

The parameters of expressions (4) and (5) used in the present discussion are as follows.
μₘₐₓ: 124 cm²/Vs
Exponent: 2.15
μₘᵢₙ₁: 8 cm²/s
μₘᵢₙ₂: 0 cm²/Vs
N_{ref}: 8×10¹⁸ cm⁻³
v(T): 0.34

In addition, the hole concentration p(T) is expressed by the following expression.

$$\begin{matrix}[ Mathematical formula 6 ] & \\ p ( T ) = \frac{{N}_{A}}{1 + \{ \frac{{g}_{A} p ( T )}{{N}_{v}} ) {e}^{\frac{Δ {E}_{A}}{k T}}} & Expression ( 6 )\end{matrix}$$

wherein, g_{A} is the degree of degeneracy of the acceptor, N_{V} is the effective state density of the valence band, ΔE_{A} is the ionization energy of the acceptor (set to 0.2 eV), and k is a Boltzmann constant. The built-in potential Vu is expressed by the following Expression.

$$\begin{matrix}[ Mathematical formula 7 ] & \\ {V}_{b i} ( T ) = {E}_{F n} - {E}_{F p} = \frac{k T}{q} ln ( \frac{{N}_{A} {N}_{D}}{{n}_{i}^{2}} ) & Expression ( 7 )\end{matrix}$$

wherein, N_{D} is the donor concentration of the n+ source and n; is the intrinsic carrier concentration of 4H—SiC. In the past documents on Si-MOSFETs, it has been reported that the failure due to the parasitic BIT is caused by positive feedback applied to the following continuous operations (1) to (6) (I. Yoshida, T. Okabe, M. Katsueda, S. Ochi, and M. Nagata, “Thermal Stability and Second Breakdown in Planar Power MOSFET's”, IEEE Transactions on Electron Devices, Vol. ED-27, No. 2, 1980, pp. 395-398).
(1) Generation of Electron Currents by Parasitic BJT Operation
(2) Drift of Electrons Due to High Electric Field in Drift Layer
(3) Generation of Electron-Hole Pairs by Collision Ionization
(4) Hole Current Passing Through P Base
(5) Reduction of Potential Barrier of P Base/n+ Source Junction
(6) Generation of Additional BJT Electron Currents

In addition, collision ionization coefficients α and B of electrons and holes are expressed as follows using the models of Loh (W. S. Loh, B. K. Ng, S. I. Soloviev, Ho-Young Cha, P. M. Sandvik, C. M. Johnson, and J. P. R. David, “Impact Ionization Coefficients in 4H—SiC”, IEEE Transactions on Electron Devices, Vol. 55, No. 8, 2008, pp. 1984-1990) and Niwa (H. Niwa, J. Suda, and T. Kimoto, “Temperature Dependence of Impact Ionization Coefficients in 4H—SiC”, Materials Science Forum, Vols. 778-780, 2014, pp. 461-466).

$$\begin{matrix}[ Mathematical formula 8 ] & \\ α = 2.78 \times {10}^{6} {e}^{- {( \frac{1.05 \times {10}^{7}}{E} )}^{1.37}} & Expression ( 8 )\end{matrix}$$

$$\begin{matrix}[ Mathematical formula 9 ] & \\ β = 4.51 \times {10}^{6} \{ 1 + 7.511 \times {10}^{- 3} ( T - 300 ) \} {e}^{- \frac{1.28 \times {10}^{7} \{ 1 + 1.381 \times {10}^{- 3} ( T - 300 ) \}}{E}} & Expression ( 9 )\end{matrix}$$

wherein, E[V/cm]is an electric field intensity, and T[K]is the lattice temperature.

Based on such a model, device simulation was performed as follows. Since SiC is a wide band gap semiconductor, it is particularly difficult to obtain ohmic contact having a low resistance with respect to p type (T. Kimoto, and J. A. Cooper, “Fundamentals of Silicon Carbide Technology”, John Wiley & Sons Singapore Pte. Ltd., 2014, p.256). In addition, there is also a report that the p type ohmic contact resistance varies between elements (Satoshi Tanimoto, Ohmic Contact Fabrication Technology for SiC Power Devices, Surface Technology, Vol. 55, No. 1, 2004, pp. 29-32). Furthermore, there is a report that the p+ contact resistance deteriorates when the size of the contact via is reduced to 20×6 μm (A. May, M. Rommel, S. Beuer, and T. Erlbacher, “Via Size-Dependent Properties of TiAl Ohmic Contacts on 4H—SiC”, Materials Science Forum, Vol. 1062, 2022, pp. 185-189). This is because the alloy layer exhibiting the ohmic characteristics does not sufficiently spread in the p+ contact via having a small area, and a cavity is formed between the p+contact via and the upper metal. That may also occur with other p+ ohmic metal materials. In addition, the size of the P+ contact of a general SiC MOSFET is several μm on one side, which is smaller than this reported example, and it is expected that the contact resistance further increases due to the cavity or the lack of the alloy layer exhibiting the ohmic characteristics in a part of the P+contact via. For this reason, the 1.2 kV SiC-DUT in FIG. 5 was divided into two DUTs in parallel on the device simulation, the inter-cell variation of the P+ contact resistance R_{c} was represented by two values, and the device simulation was performed (see FIG. 12). As a result, it was possible to reproduce the parasitic BJT operation and the subsequent failure similarly to the actual measurement.

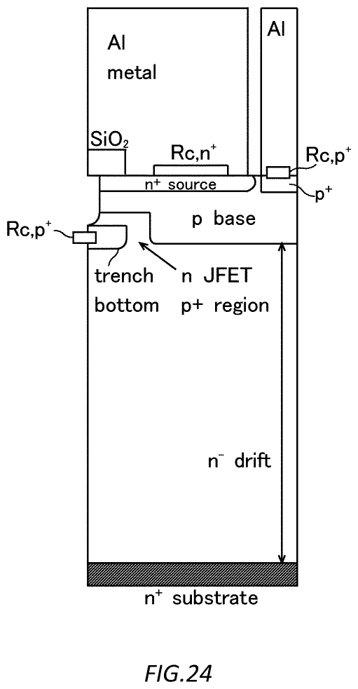

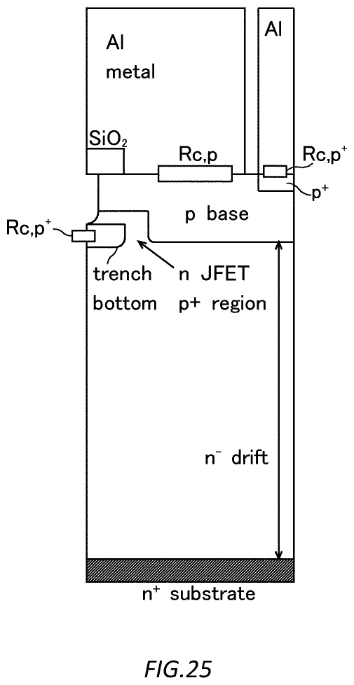

Of the two DUTs, one corresponds to most of the active region having a relatively low P⁺contact resistance, and the other DUT corresponds to a local active region (2% of the total) having a high P+ contact resistance, which will be referred to as a “main-DUT (corresponding to the SiC chip 22-2)” and a “local-DUT (corresponding to the SiC chip 22-1)”, respectively. Although the P+ contact resistance is considered to be continuously distributed over a wide range within an element and between elements, the P+ contact resistance of the local-DUT was set to be 10 times that of the main-DUT for model simplification. The device structures of the SiC trench MOSFET and the SiC trench diode are illustrated in FIGS. 24 and 25. In these device models, separate electrodes were set for the n+ source, the P+ surface, and the P+ well below the trench, respectively, and the contact resistance was set at the SiC and electrode metal interface of each electrode. In the SiC trench MOSFET, a sufficiently low series resistance R_{c,n+} is connected to the n+ source electrode. For the series resistance R_{c,P+} of the P+ electrode, the local-DUT was set to be 10 times higher than that of the main-DUT as described above. In addition, in the SiC trench diode, substantially high series resistance R_{c,p-} are set in the p base electrode to prevent electric conduction at the p base/Al metal interface.

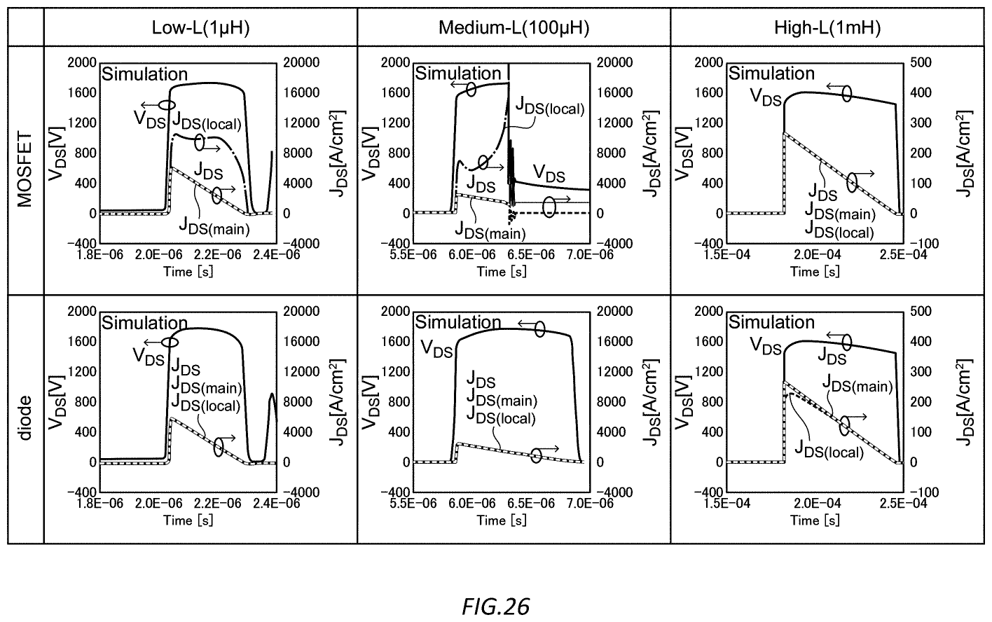

FIG. 26 illustrates simulation waveforms of the SiC trench MOSFET and the SiC trench diode at load inductances of 1 μH (Low-L), 10 μH (Medium-L), and 5 mH (High-L). At this time, the maximum drain current in the UIS test is set similarly to the actual measurement. From these waveforms, the waveform of the SiC trench MOSFET in the Medium-L region is significantly different from the waveforms under other conditions. The drain current of the local-MOSFET gradually increases with the post avalanche breakdown time and finally diverges. Thereafter, the drain current of the main-MOSFET disappears, and V_{DS} greatly decreases from about 1.7 kV to about 400 V, which indicates the element failure. A simulation result in which the avalanche capability of the SiC trench MOSFET is lower than that of the SiC trench diode under the same condition only in the Medium-L region, and on the other hand, in the Low-L region and the High-L region, the avalanche capabilities of both are substantially the same is obtained, which effectively reproduces the measurement results of FIGS. 7, 8, 16, 17, and 19.

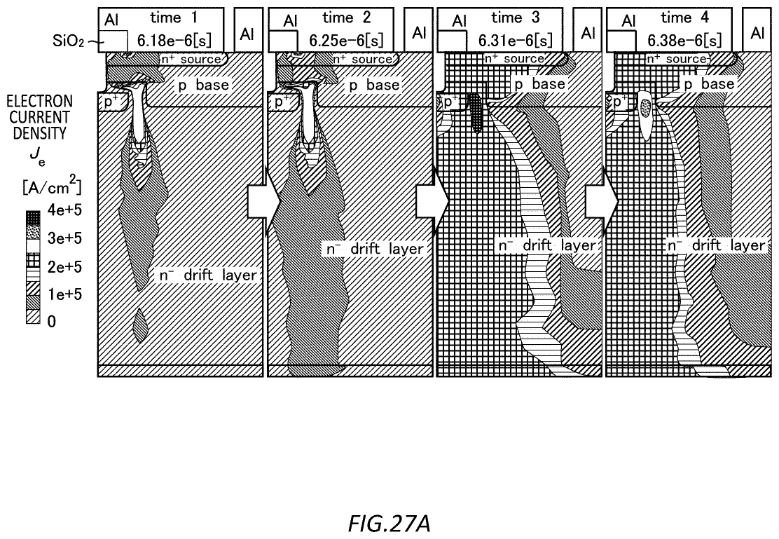

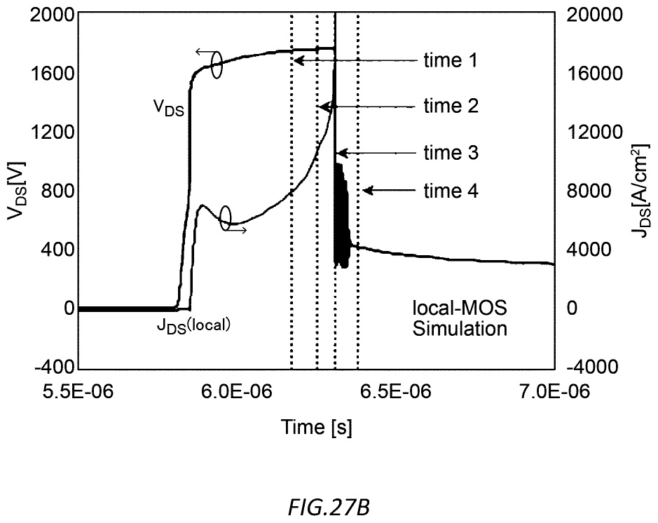

FIG. 27A illustrates a schematic view of the electron current density distribution in the device cross section at times 1, 2, 3, and 4 described in the SiC trench MOSFET waveform in the Medium-L region in FIG. 26. In FIG. 27B, times 1, 2, 3, and 4 are illustrated. The electron current due to the parasitic BJT operation flows through the JFET region, but the electron current rapidly increases at times 3 and 4 after the element failure. Therefore, it is considered that the element failure of the MOSFET in the Medium-L region is caused by application of positive feedback to the electron current due to local parasitic BJT operation.

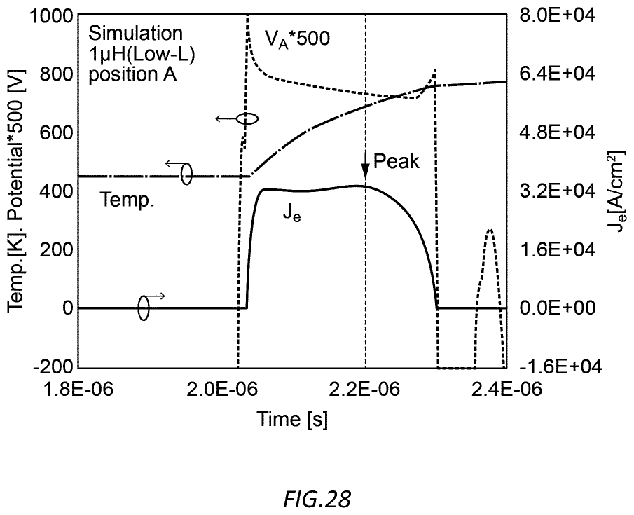

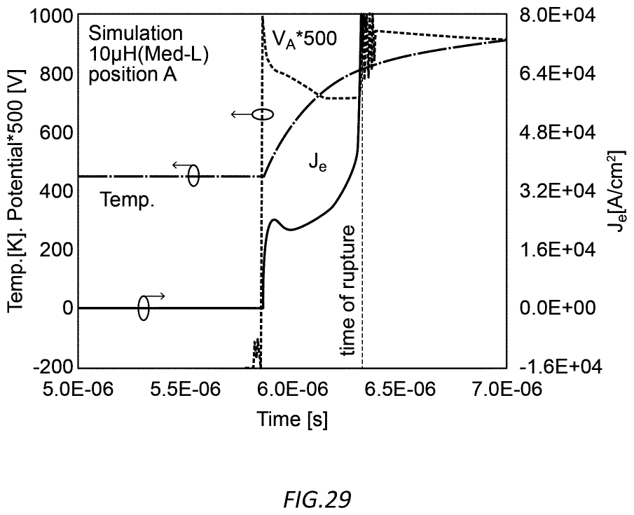

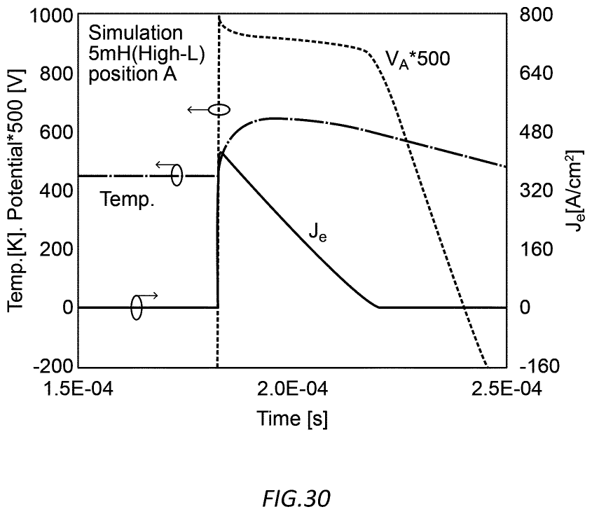

FIGS. 28, 29, and 30 are temporal changes of the electron current density Jₑ, the lattice temperature, and the potential V_{A} at the point A indicated in the p base of the SiC trench MOSFET in FIG. 27A at load inductances of 1 μH (Low-L), 10 μH (Medium-L), and 5 mH (High-L). In the Medium-L region of FIG. 29, since the P+ contact resistance is high, V_{A} becomes low, and as a result, the electron current Jₑ due to the parasitic BJT operation becomes large, so that the temperature rapidly rises. The lattice temperature in the simulation reached about 800 K at the time of failure and the highest temperature between each inductance region. In addition, the potential V_{A} at the point A at the time of failure was 1.44 V, which was the lowest. Therefore, it is considered that the positive feedback of the electron current Jₑ flowing by the operation of the parasitic BJT occurs.

In the High-L region, Jₑ is 2 orders of magnitude lower than in the Medium-L region, and the maximum lattice temperature in the simulation remains at about 650 K. In addition, since the potential V_{A} of the point A is maintained as high as 1.75 V, it is considered that the positive feedback of the electron current by the parasitic BJT operation does not occur. Furthermore, in the Low-L region, Jₑ at the start of avalanche breakdown is much higher than in the Medium-L region, and the potential V_{A} at the peak of Jₑ also greatly decreases to 1.47 V. However, since the duration of the avalanche breakdown is shorter than that in the Medium-L region, the rise in the lattice temperature in the simulation is 690 K at the Jₑ peak, which is also low in this case. Therefore, since the parasitic BJT operates, but the avalanche period ends before the positive feedback of the electron current Jₑ occurs, it is considered that element failure triggered by the parasitic BJT operation does not occur. Also in past Si bipolar transistors, a report similar to this simulation result has been made that a sufficient time is required to cause secondary breakdown (H. Melchior, and M. J. O. Strutt, “Secondary breakdown in transistors”, Proceedings of the IEEE, Vol. 52, 1964, pp. 439-440).

### (Possibility of Failure Mechanism by Reduction of Gate Threshold Voltage Vₜₕ)

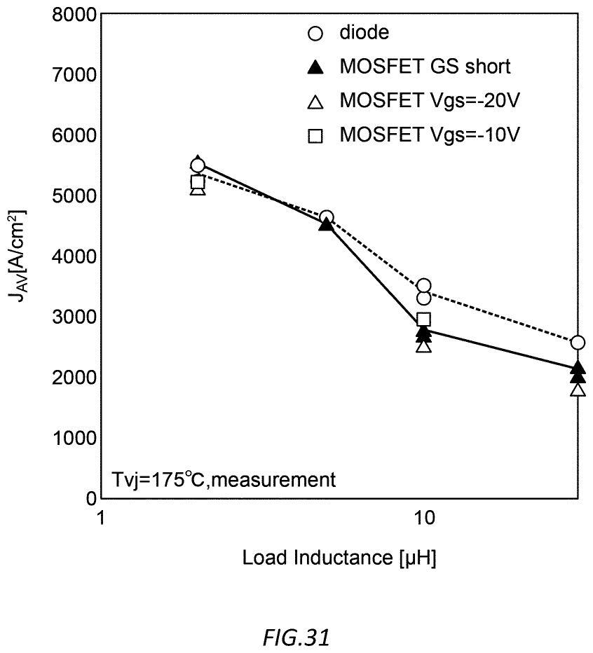

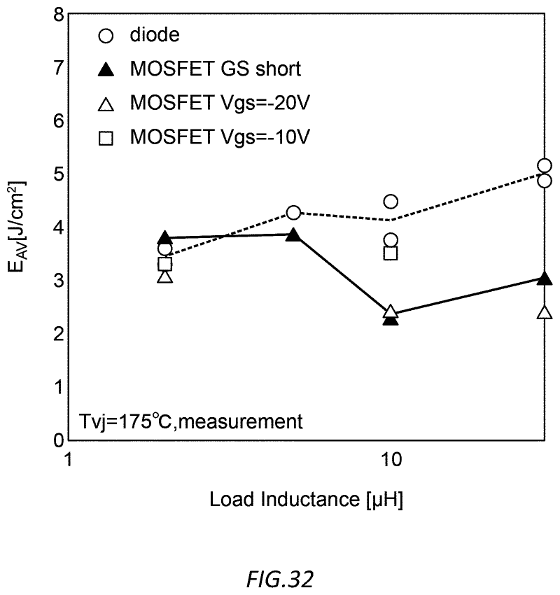

Another avalanche breakdown mechanism is a decrease in Vₜₕ due to a high lattice temperature and a MOS channel current associated therewith. In order to verify this mechanism, the gate V_{DS} of the DUT was set to −10 V or −20 V, and the avalanche capability at the load inductance of 2 μH to 30 μH (from the Low-L region to a part of the Medium-L region) was evaluated. As a result, as illustrated in FIGS. 31 and 32, no improvement in the avalanche capability is observed even when the gate negative bias is deepened.

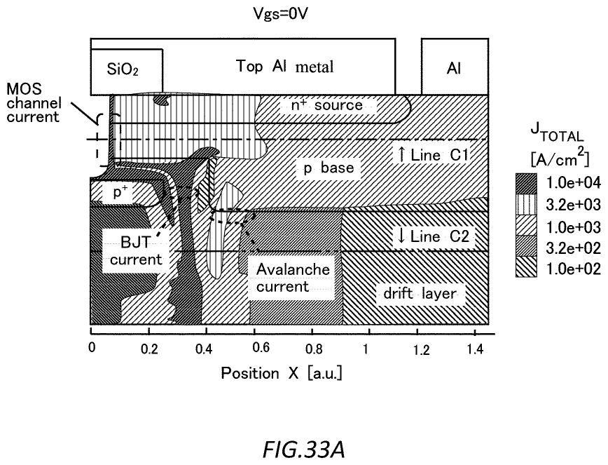

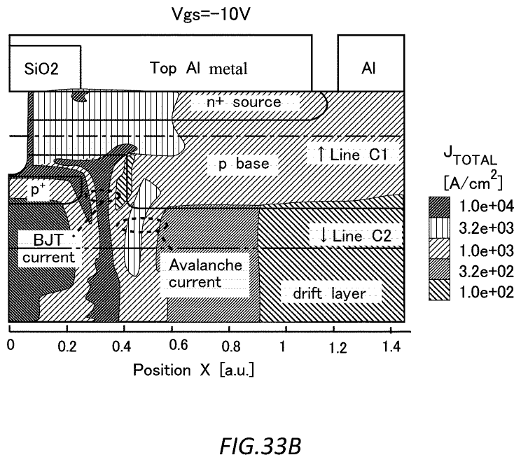

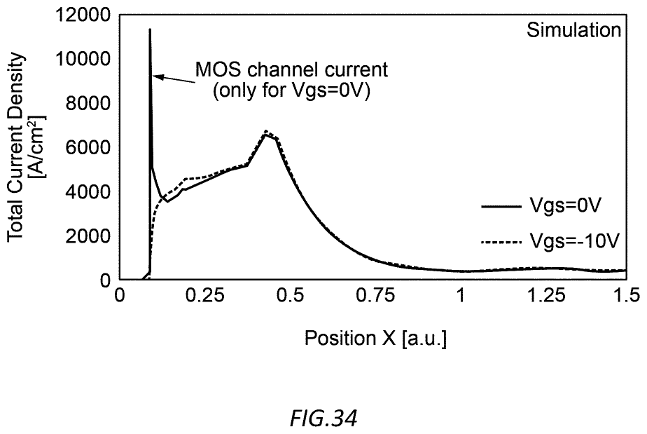

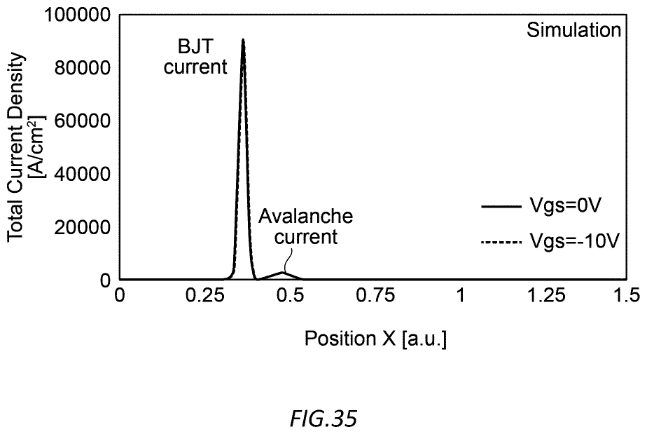

In addition, also in the device simulation, the decrease in Vₜₕ at 30 μH in the Medium-L region and the MOS channel current associated therewith were verified. As illustrated in FIGS. 33A and 33B, the MOS channel current can be checked only when V_{GS}=0 V (FIG. 33A). The total current density distribution at V_{GS}=0 V, −10 V in the upper line C1 of FIGS. 33A and 33B is illustrated in FIG. 34. Although the maximum MOS channel current of about 1.1×104 A/cm² can be checked under the condition of V_{GS}=0 V, this ratio is merely about 2.2% of the total current. Furthermore, the current density distribution at the same V_{GS} condition in a lower line C2 of FIGS. 33A and 33B is illustrated in FIG. 35. The electron current from the JFET region and the avalanche current from the lower corner of the p base are checked, and the distribution of the electron current from the JFET region in the case of V_{GS}=0 V is not clearly different from that in the case of V_{GS}=−10 V. From these results, it is considered that there is a substantially small possibility that the decrease in Vₜₕ and the MOS channel current associated therewith enter the positive feedback, and a defective mode in which an element fails occurs.

### (Conclusion of Discussion)

In this discussion, the load inductance was changed in a wide range of 1 μH to 5 mH in the UIS circuit, and the avalanche capability and the failure mechanism of the 1.2 kV SiC trench MOSFET were investigated and verified. At 1 μH close to the parasitic inductance of the power module, an avalanche allowable current density of about 6000 A/cm² was obtained for the SiC trench MOSFET, which was shown to be about 3.3 times that of the Si-IGBT. This allows more chips to be connected in parallel in the power module in the SiC-MOSFET than in the Si-IGBT, and contributes to reduction of the chip size and improvement of the non-defective product rate.

The avalanche breakdown mechanism of the SiC trench MOSFET was verified by comparing the avalanche capability of the SiC trench MOSFET with that of the SiC trench diode manufactured by intentionally removing only the n+ source. In the SiC trench MOSFET, the avalanche capability was lower than that of the SiC trench diode only in 10 μH to 100 μH (Medium-L region) at 175° C., and the avalanche capability was almost the same in at most 10 μH (Low-L region) and 300 μH or more (High-L region). The avalanche breakdown of the SiC trench MOSFET in the Medium-L region caused by the parasitic npn BJT operation and the positive feedback of the electron current could be reproduced by introducing the inter-cell variation of the p+ contact resistance in the device simulation. In addition, a measurement result was obtained in which the avalanche capability hardly depends on the gate negative bias voltage of the DUT. Therefore, it was concluded that in the SiC trench MOSFET in this Medium-L region, the element failure occurred due to the parasitic BJT operation and the positive feedback of the electron current. In addition, in at most 10 μH (Low-L region) and 100 uH or more (High-L region) in the SiC trench MOSFET, the lattice temperature estimated from the actually measured V_{DS} waveform reaches 900 K under any condition, and a large number of holes are observed in the secondary electron microscope of the Al source metal surface of the SiC trench MOSFET, and thus it is presumed that in the SiC trench MOSFET in these regions of load inductance, the element failure occurs in association with melting of the Al source metal.

While the present invention has been described with the embodiments, the technical scope of the present invention is not limited to the above-described embodiments. It is apparent to persons skilled in the art that various alterations and improvements can be added to the above-described embodiments. It is also apparent from the scope of the claims that the embodiments added with such alterations or improvements can be included in the technical scope of the present invention.

### EXPLANATION OF REFERENCES

10: control unit; 12: current sensing unit; 20: switching unit; 21: upper surface; 22: SiC chip; 30: semiconductor substrate; 32: drift region; 33: region; 34: drain region; 36: base region; 38: source region; 40: region; 42: lower end region; 44: contact region; 45: protrusion; 47: contact trench portion; 50: source electrode; 51: upper end; 52: drain electrode; 53: upper end; 54: interlayer dielectric film; 60: gate trench portion; 61: mesa portion; 62: gate dielectric film; 64: gate electrode; 100: semiconductor module; 122: SiC chip; 200: measurement circuit; 202: drive device; 204: load inductor; 206: power supply; 208: gate resistor; 209: gate resistor; 210: pulse generator; and 212: gate control unit.

What is claimed is:

1. A semiconductor module comprising:
a plurality of SiC chips electrically connected in parallel and each having a MOSFET and a parasitic transistor that are formed therein; and
a control unit which controls switching of the MOSFET in each of the plurality of SiC chips, wherein
for all of the plurality of SiC chips, at least in a state where the parasitic transistor is turned on, the control unit controls, to 0.9 μs or less, a turn-off time of the MOSFET corresponding.

2. The semiconductor module according to claim 1, wherein
the parasitic transistor of each of the plurality of SiC chips is not turned on in a region where a current density of a main current flowing through the MOSFET corresponding is 6000 A/cm² or less.

3. The semiconductor module according to claim 1, wherein
even in a state where the parasitic transistor is turned off, the control unit controls, to 0.9 μs or less, the turn-off time of the MOSFET corresponding.

4. The semiconductor module according to claim 1, wherein
in a state where the parasitic transistor is turned off, the control unit controls, to a value larger than 0.9 μs, the turn-off time of the MOSFET corresponding.

5. The semiconductor module according to claim 4, wherein
the control unit collectively controls the turn-off times of the MOSFETs of all of the plurality of SiC chips.

6. The semiconductor module according to claim 4, wherein
depending on a state of the parasitic transistor of each of the plurality of SiC chips, the control unit individually controls the turn-off time of the MOSFET corresponding.

7. The semiconductor module according to claim 4, further comprising:
a current sensing unit which senses a main current flowing through the MOSFET of at least one of the plurality of SiC chips, wherein
the control unit controls the turn-off time of the MOSFET of the at least one of the plurality of SiC chips based on a waveform of the main current sensed by the current sensing unit.

8. The semiconductor module according to claim 7, wherein
the control unit controls the turn-off time of the MOSFET of the at least one of the plurality of SiC chips based on a slope of a rising edge of the waveform of the main current sensed by the current sensing unit.

9. The semiconductor module according to claim 1, wherein
an acceptor concentration of a base region of the MOSFET of each of the plurality of SiC chips is 1×10¹⁷/cm³ or more.

10. The semiconductor module according to claim 9, wherein
the acceptor concentration of the base region of the MOSFET of each of the plurality of SiC chips is 8×10¹⁷/cm³ or more.

11. The semiconductor module according to claim 1, wherein
a maximum value of a contact resistance of a contact region of the MOSFET of each of the plurality of SiC chips is 9.0 mΩcm² or less.

12. The semiconductor module according to claim 1, wherein
each of the plurality of SiC chips includes a semiconductor substrate formed of SiC, having an upper surface and provided with the MOSFET,
the semiconductor substrate has:
one or more gate trench portions provided from the upper surface to inside of the semiconductor substrate;
a source region of a first conductivity type provided in contact with a corresponding one of the one or more gate trench portions on the upper surface; and
a contact region of a second conductivity type provided on the upper surface, and the contact region has a protrusion protruding upward from the source region.

13. The semiconductor module according to claim 12, wherein
the one or more gate trench portions are provided to extend in a first direction on the upper surface,
the contact region has a first width in a second direction parallel to the upper surface and orthogonal to the first direction, and
a protrusion length by which the protrusion protrudes from the source region is equal to or larger than the first width.

14. The semiconductor module according to claim 12, wherein
each of the one or more gate trench portions is provided to extend in a first direction on the upper surface,
the semiconductor substrate has one or more mesa portions, each of which is sandwiched between corresponding two of the one or more gate trench portions in a second direction parallel to the upper surface and orthogonal to the first direction, and
the protrusion includes a plurality of protrusions, and in one of the one or more mesa portions, the contact region has the plurality of protrusions.

15. The semiconductor module according to claim 14, wherein
the plurality of protrusions is arranged in the second direction.

16. The semiconductor module according to claim 14, wherein
the plurality of protrusions is arranged in the first direction.

17. The semiconductor module according to claim 12, wherein
the source region is in contact with the contact region, and
an upper end of the source region at a position at which the source region is in contact with the contact region is disposed below an upper end of the corresponding one of the one or more gate trench portions.

18. The semiconductor module according to claim 17, wherein
the semiconductor substrate further has a contact trench portion which includes a boundary position between the source region and the contact region and which is disposed in each region of the source region and the contact region.

19. The semiconductor module according to claim 2, wherein
even in a state where the parasitic transistor is turned off, the control unit controls, to 0.9 μs or less, the turn-off time of the MOSFET corresponding.

20. The semiconductor module according to claim 2, wherein
in a state where the parasitic transistor is turned off, the control unit controls, to a value larger than 0.9 μs, the turn-off time of the MOSFET corresponding.
